(19) United States
(12) Patent Application Publication
(10) Pub. No.: US 2024/0431144 A1
(43) Pub. Date: Dec. 26, 2024

(54) DISPLAY SUBSTRATE, MANUFACTURING METHOD THEREOF AND DISPLAY DEVICE

(71) Applicants: Chengdu BOE Optoelectronics Technology Co., Ltd., Chengdu (Sichuan) (CN); BOE TECHNOLOGY GROUP CO., LTD., Beijing (CN)

(72) Inventors: Fei LIU, Beijing (CN); Xin JIN, Beijing (CN); Lei FAN, Beijing (CN); Liangyun LI, Beijing (CN); Qinbo REN, Beijing (CN); Chunfang FAN, Beijing (CN); Ying LIU, Beijing (CN); Wei ZHANG, Beijing (CN); Xiaoliang GUO, Beijing (CN); Lei DENG, Beijing (CN); Nuo SHI, Beijing (CN)

(73) Assignees: Chengdu BOE Optoelectronics Technology Co., Ltd., Chengdu (Sichuan) (CN); BOE TECHNOLOGY GROUP CO., LTD., Beijing (CN)

(21) Appl. No.: 18/274,077

(22) PCT Filed: Aug. 30, 2022
(86) PCT No.: PCT/CN2022/115829

§ 371 Date: Jul. 25, 2023

(51) Int. Cl. H10K 59/122; H10K 59/12; H10K 59/80

(52) U.S. Cl. CPC H10K 59/122; H10K 59/1201; H10K 59/80521

(57) ABSTRACT

A display substrate, a manufacturing method thereof, and a display device are provided. The display substrate includes a base substrate and sub-pixels. The sub-pixel includes a light-emitting element which includes a light-emitting functional layer and a first electrode and a second electrode. The display substrate further includes a defining structure, a first orthographic projection of a surface, close to the base substrate, of the defining structure between adjacent sub-pixels on the base substrate is completely within a second orthographic projection of a surface, away from the base substrate, of the defining structure on the base substrate, a maximum size of the second orthographic projection is greater than that of the first orthographic projection, and the defining structure includes an inorganic nonmetallic material; the light-emitting functional layer is disconnected at an edge of the defining structure, and second electrodes of adjacent sub-pixels are at least partially continuously arranged.

### TECHNICAL FIELD

Embodiments of the present disclosure relate to a display substrate, a manufacturing method thereof and a display device.

### BACKGROUND

With the development of display technology, users have higher and higher requirements for the performance of display devices. Isolating some material layers used for illumination between adjacent sub-pixels can reduce signal crosstalk, thus meeting the performance requirements of high brightness and low power consumption of display devices as much as possible.

### SUMMARY

Embodiments of the present disclosure provides a display substrate and a display device.

An embodiment of the present disclosure provides a display substrate, which includes a base substrate and a plurality of sub-pixels located on the base substrate. The base substrate at least includes a first region; the plurality of sub-pixels are located in the first region, each sub-pixel in at least part of the plurality of sub-pixels includes a light-emitting element, the light-emitting element includes a light-emitting functional layer, and a first electrode and a second electrode located at both sides of the light-emitting functional layer along a direction perpendicular to the base substrate, the first electrode is located between the light-emitting functional layer and the base substrate, and the light-emitting functional layer includes a plurality of film layers. The display substrate further includes a defining structure, and at least one defining structure is disposed between at least two adjacent sub-pixels; a first orthographic projection of a surface, close to the base substrate, of the defining structure between adjacent sub-pixels on the base substrate is completely located within a second orthographic projection of a surface, away from the base substrate, of the defining structure on the base substrate; in an arrangement direction of light-emitting regions of the adjacent sub-pixels, a maximum size of the second orthographic projection is greater than a maximum size of the first orthographic projection, and the defining structure includes an inorganic nonmetallic material; in at least a partial region of the first region, at least one film layer in the light-emitting functional layer is disconnected at an edge of the defining structure, and second electrodes of adjacent sub-pixels are at least partially continuously arranged.

For example, according to an embodiment of the present disclosure, the second electrodes are continuously arranged at the edge of the defining structure.

For example, according to an embodiment of the present disclosure, the second electrode of at least one sub-pixel and the second electrode of one sub-pixel adjacent thereto in a first sub-direction are continuously arranged, the second electrode of the at least one sub-pixel and the second electrode of one sub-pixel adjacent thereto in a second sub-direction are disconnected, and the first sub-direction is intersected with the second sub-direction; and/or, the second electrode of at least one sub-pixel and the second electrode of one sub-pixel adjacent thereto in a first sub-direction are continuously arranged, the second electrode of the at least one sub-pixel and the second electrode of one sub-pixel adjacent thereto in a second sub-direction are continuously arranged, and the first sub-direction is intersected with the second sub-direction.

For example, according to an embodiment of the present disclosure, the defining structure surrounds more than 50% of an outline of at least one sub-pixel.

For example, according to an embodiment of the present disclosure, the second electrode of at least one sub-pixel and the second electrode of one sub-pixel adjacent thereto are continuously arranged, and a minimum width of the second electrode between these two adjacent sub-pixels is greater than 1 micron in a direction perpendicular to an arrangement direction of these two adjacent sub-pixels.

For example, according to an embodiment of the present disclosure, an orthographic projection of a center connecting line of these two adjacent sub-pixels on a plane where the second electrode is located is within the second electrode.

For example, according to an embodiment of the present disclosure, outlines of at least part of the defining structures are the same as outlines of light-emitting regions of sub-pixels surrounded by the at least part of the defining structures, and a ratio of distances between adjacent edges of different defining structures and light-emitting regions of corresponding sub-pixels surrounded by the different defining structures is in a range of 0.9-1.1.

For example, according to an embodiment of the present disclosure, a cross-sectional shape of the defining structure cut by a plane where the center connecting line is located includes a first trapezoid, a length of a first base of the first trapezoid away from the base substrate is greater than a length of a second base of the first trapezoid close to the base substrate, and the plane is perpendicular to the base substrate.

For example, according to an embodiment of the present disclosure, an included angle between at least part of at least one leg of the first trapezoid and the second base is in a range of 110-150 degrees.

For example, according to an embodiment of the present disclosure, a thickness of the defining structure is in a range of 300-550 angstroms.

For example, according to an embodiment of the present disclosure, the display substrate further includes: a first insulating layer, located between the defining structure and the base substrate. In at least the partial region of the first region, the first insulating layer is in contact with the surface of the defining structure facing the base substrate, the first insulating layer is located between the first electrode and the base substrate, and a material of the first insulating layer includes an organic material.

For example, according to an embodiment of the present disclosure, the first insulating layer includes a protrusion in contact with the surface of the defining structure, and the first orthographic projection is completely located within an orthographic projection of the protrusion on the base substrate.

For example, according to an embodiment of the present disclosure, a distance between orthographic projections of an edge of the protrusion and an edge of the surface, away from the base substrate, of the defining structure on the base substrate is less than 0.5 micron.

For example, according to an embodiment of the present disclosure, a surface of the first electrode is in contact with a surface of the first insulating layer, and a distance between a surface of the first electrode away from the base substrate and the base substrate is less than a distance between the surface of the defining structure away from the base substrate and the base substrate.

For example, according to an embodiment of the present disclosure, the display substrate further includes: a pixel defining pattern, located at a side of the first electrode away from the base substrate, at least the pixel defining pattern located in the first region includes a plurality of first openings, one sub-pixel corresponds to at least one first opening, the light-emitting element of the sub-pixel is at least partially located in the first opening corresponding to the sub-pixel, and the first opening is configured to expose the first electrode. The pixel defining pattern further includes a second opening, and at least part of the defining structure is exposed by the second opening.

For example, according to an embodiment of the present disclosure, at least one film layer in the light-emitting functional layer is disconnected at at least part of an edge of the defining structure exposed by the second opening, and the second electrode is continuously arranged at the edge of the defining structure.

For example, according to an embodiment of the present disclosure, at least one film layer in the light-emitting functional layer includes a charge generation layer, the light-emitting functional layer includes a first light-emitting layer, the charge generation layer and a second light-emitting layer which are stacked, the charge generation layer is located between the first light-emitting layer and the second light-emitting layer, and the charge generation layer is disconnected at the edge of the defined structure.

For example, according to an embodiment of the present disclosure, the plurality of sub-pixels includes a plurality of first color sub-pixels, a plurality of second color sub-pixels and a plurality of third color sub-pixels, the defining structure includes a plurality of first annular defining structures, and the plurality of first annular defining structures surrounds at least one sub-pixel among the plurality of first color sub-pixels, the plurality of second color sub-pixels and the plurality of third color sub-pixels.

For example, according to an embodiment of the present disclosure, each sub-pixel in the at least part of the plurality of sub-pixels further includes a pixel circuit, and the first electrode of the light-emitting element of at least one sub-pixel includes a main electrode and a connection electrode, and in the direction perpendicular to the base substrate, the main electrode overlaps with the light-emitting region of the light-emitting element, and the connection electrode does not overlap with the light-emitting region of the light-emitting element; the pixel circuit is electrically connected to the connection electrode, and the first annular defining structure surrounding the at least one sub-pixel includes a notch, and in the direction perpendicular to the base substrate, the first annular defining structure does not overlap with the connection electrode.

For example, according to an embodiment of the present disclosure, the display substrate further includes: a second insulating layer, located between the defining structure and the base substrate. The base substrate further includes a second region, and the first region is located at a periphery of the second region; the second insulating layer includes at least one annular insulating portion surrounding the second region, the defining structure further includes a second annular defining structure in contact with a surface, away from the base substrate, of the annular insulating portion, the second insulating layer is located at a side of the first insulating layer facing the base substrate, a material of the second insulating layer includes an inorganic nonmetallic material, the material of the second insulating layer is different from the material of the defining structure, and the light-emitting functional layer and the second electrode are both disconnected at an edge of the second annular defining structure.

For example, according to an embodiment of the present disclosure, a cross-section of the second annular defining structure includes a second trapezoid, and a length of a base of the second trapezoid away from the base substrate is greater than a length of a base of the second trapezoid close to the base substrate.

For example, according to an embodiment of the present disclosure, an orthographic projection of the second annular defining structure on the base substrate is located within an orthographic projection of the annular insulating portion on the base substrate.

For example, according to an embodiment of the present disclosure, a ratio of a size of the first trapezoid in the direction perpendicular to the base substrate to a size of the second trapezoid in the direction perpendicular to the base substrate is in a range of 0.8-1.2, and a ratio of an included angle between a leg of the first trapezoid and the second base to an included angle between a leg of the second trapezoid and the base of the second trapezoid close to the base substrate is in a range of 0.8-1.2.

Another embodiment of the present disclosure provides a display substrate, which includes a base substrate and a plurality of sub-pixels located on the base substrate. The base substrate at least includes a first region; the plurality of sub-pixels are located in the first region, each sub-pixel in at least part of the plurality of sub-pixels includes a light-emitting element, the light-emitting element includes a light-emitting functional layer, and a first electrode and a second electrode located at both sides of the light-emitting functional layer along a direction perpendicular to the base substrate, the first electrode is located between the light-emitting functional layer and the base substrate, and the light-emitting functional layer includes a plurality of film layers. The display substrate further includes a defining structure, at least one defining structure is disposed between at least two adjacent sub-pixels, the plurality of sub-pixels includes a first sub-pixel, a second sub-pixel and a third sub-pixel, the second sub-pixel and the third sub-pixel are both adjacent to the first sub-pixel, a maximum size of the defining structure disposed between the first sub-pixel and the second sub-pixel in an arrangement direction of these two sub-pixels is a first size, a maximum size of the defining structure disposed between the first sub-pixel and the third sub-pixel in an arrangement direction of these two sub-pixels is a second size, and the first size is different from the second size.

For example, according to an embodiment of the present disclosure, the plurality of sub-pixels is arrayed along a first direction and a second direction, some pixels in the plurality of sub-pixels are arrayed along a third direction and a fourth direction, the first direction is perpendicular to the second direction, the third direction is perpendicular to the fourth direction, and the first direction is intersected with the third direction; a maximum size of the defining structure between two adjacent sub-pixels arranged along the first direction or the second direction in an arrangement direction of these two sub-pixels is a third size, a maximum size of the defining structure between two adjacent sub-pixels arranged along the third direction or the fourth direction in an arrangement direction of these two sub-pixels is a fourth size, and the third size is less than the fourth size.

For example, according to an embodiment of the present disclosure, the plurality of sub-pixels includes a plurality of green sub-pixels, a plurality of blue sub-pixels and a plurality of red sub-pixels, and a maximum size of the defining structure disposed between two adjacent green sub-pixels in an arrangement direction of these two green sub-pixels is greater than a maximum size of the defining structure disposed between other adjacent sub-pixels in an arrangement direction of the other adjacent sub-pixels.

For example, according to an embodiment of the present disclosure, each sub-pixel in the at least part of the plurality of sub-pixels further includes a pixel circuit, the first electrode of the light-emitting element of at least one sub-pixel includes a main electrode and a connection electrode; and in the direction perpendicular to the base substrate, the main electrode overlaps with the light-emitting region of the light-emitting element, the connection electrode does not overlap with the light-emitting region of the light-emitting element, and the pixel circuit is electrically connected to the connection electrode; in at least a partial region of the first region, at least one film layer in the light-emitting functional layer is disconnected at an edge of the defining structure, and at least part of the second electrode is continuously arranged at an overlapping position with the connection electrode.

For example, according to an embodiment of the present disclosure, in the direction perpendicular to the base substrate, the defining structure does not overlap with at least part of the connection electrode.

For example, according to an embodiment of the present disclosure, the second electrodes in the at least part of the plurality of sub-pixels include a planar structure or a mesh structure.

Another embodiment of the present disclosure provides a display device, which includes any display substrate as mentioned above.

Another embodiment of the present disclosure provides a manufacturing method of a display substrate, which includes: providing a base substrate; forming an inorganic nonmetallic material layer on the base substrate; forming a shielding structure at a side of the inorganic nonmetallic material layer away from the base substrate; etching, by taking the shielding structure as a mask and using a first gas, the inorganic nonmetallic material layer to form a defining pattern; etching, by taking the shielding structure as a mask and using a second gas, the defining pattern to form a defining structure; forming a plurality of sub-pixels in at least a first region of the base substrate. At least one defining structure is disposed between at least two adjacent sub-pixels, each sub-pixel in at least part of the plurality of sub-pixels includes a light-emitting element, forming the light-emitting element includes sequentially forming a first electrode, a light-emitting functional layer and a second electrode which are stacked in a direction perpendicular to the base substrate, the first electrode is located between the second electrode and the base substrate, and the light-emitting functional layer includes a plurality of film layers; a first orthographic projection of a surface, close to the base substrate, of the defining structure between adjacent sub-pixels on the base substrate is completely located within a second orthographic projection of a surface, away from the base substrate, of the defining structure on the base substrate; in an arrangement direction of light-emitting regions of the adjacent sub-pixels, a maximum size of the second orthographic projection is greater than a maximum size of the first orthographic projection; in at least a partial region of the first region, at least one film layer in the light-emitting functional layer is disconnected at an edge of the defining structure, and second electrodes of adjacent sub-pixels are at least partially continuously arranged.

For example, according to an embodiment of the present disclosure, a cross-sectional shape of the defining pattern cut by a plane where the center connecting line is located includes a rectangle, a cross-sectional shape of the defining structure cut by the plane includes a first trapezoid, a length of a base of the first trapezoid away from the base substrate is greater than a length of a base of the first trapezoid close to the base substrate, and the plane is perpendicular to the base substrate.

For example, according to an embodiment of the present disclosure, after forming the defining structure, the manufacturing method further includes: removing the shielding structure.

For example, according to an embodiment of the present disclosure, before forming the inorganic nonmetallic material layer, the manufacturing method further includes: forming a first insulating layer on the base substrate, in which, in a partial region of the first region, the inorganic nonmetallic material layer is formed on a surface of the first insulating layer; before forming the first insulating layer, the manufacturing method further includes: forming a second insulating layer on the base substrate, in which, in another partial region of the first region, the inorganic nonmetallic material layer is formed on a surface of the second insulating layer; etching, by using the first gas, the inorganic nonmetallic material layer to form the defining pattern includes simultaneously etching the inorganic nonmetallic material layer on the first insulating layer and the inorganic nonmetallic material layer on the second insulating layer to form the defining pattern; etching, by using the second gas, the defining pattern to form the defining structure includes simultaneously etching the defining pattern on the first insulating layer and the defining pattern on the second insulating layer to form the defining structure.

### BRIEF DESCRIPTION OF DRAWINGS

In order to clearly illustrate the technical solution of the embodiments of the invention, the drawings of the embodiments will be briefly described in the following; it is obvious that the described drawings are only related to some embodiments of the present disclosure and thus are not limitative of the present disclosure.

FIG. 1 is a planar view of a display substrate provided by an embodiment of the present disclosure;

FIG. 2 is a schematic diagram of a defining structure and sub-pixels in a partial region A11 as shown in FIG. 1;

FIG. 3 is a partial cross-sectional structural view taken along line BB′ as shown in FIG. 2;

FIG. 4A is an enlarged view of a region C as shown in FIG. 3;

FIG. 4B is an enlarged view of a region C as shown in FIG. 3 according to a different example;

FIG. 5 is a partial cross-sectional structural view of a display substrate provided by another example of the embodiment of the present disclosure;

FIGS. 6 and 7A are partial planar structural views of a display substrate provided by different examples of the embodiment of the present disclosure;

FIG. 7B is a planar view of a second electrode covering a defining structure provided by an embodiment of the present disclosure;

FIG. 8 is a partial cross-sectional structural view taken along line DD′ as shown in FIG. 2;

FIG. 9A is a partial cross-sectional structural view taken along line EE′ as shown in FIG. 1;

FIG. 9B is a cross-sectional structural view of a partial of a first region close to a second region provided by an example of the embodiment of the present disclosure;

FIG. 10 is a schematic block diagram of a display device provided by another embodiment of the present disclosure.

FIGS. 11A-11E are schematic process flow charts of a manufacturing method of a partial region of a display substrate provided by an embodiment of the present disclosure;

FIGS. 12A-12C are schematic process flow charts of a manufacturing method of another partial region of a display substrate provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects.

In the embodiment of the present disclosure, the features, “parallel to,” “perpendicular to,” “identical to,” etc., all include the features “parallel to,” “perpendicular to,” “identical to,” etc., in the strict sense, as well as the cases containing certain errors, such as “approximately parallel to,” “approximately perpendicular to,” “approximately identical to,” etc. Considering the measurement and the errors related to the measurement of a specific quantity (e.g., the limitation of the measurement system), they are within an acceptable deviation range for the specific quantity determined by those skilled in the art. For example, the term “approximately” can mean within one or more standard deviations, or within 10% or 5% deviation of the stated value. When the quantity of a component is not specified in the following description of the embodiments of the present disclosure, it means that the number of the component can be one or more, or can be understood as at least one. The phrase “at least one” means one or more, and the phrase “plurality of” means at least two.

In research, the inventor(s) of the present application have noticed that: the light-emitting functional layer of a light-emitting element can include multi-layer light-emitting layers which are stacked, a charge generation layer (CGL) is disposed between at least two layers of the multi-layer light-emitting layers, and the charge generation layer has a relatively high conductivity; in the case where the charge generation layer is a whole-surface film layer, the charge generation layers of two adjacent light-emitting elements are the continuous film layer, which easily leads to crosstalk between adjacent sub-pixels and color shift of the display substrate. For example, the charge generation layer is easy to cause crosstalk between sub-pixels of different colors at low brightness, resulting in low gray scale color shift.

Embodiments of the present disclosure provide a display substrate, a manufacturing method thereof, and a display device. The display substrate includes a base substrate and a plurality of sub-pixels located on the base substrate. The base substrate at least includes a first region; the plurality of sub-pixels is located in the first region, each sub-pixel in at least some sub-pixels includes a light-emitting element, the light-emitting element includes a light-emitting functional layer and a first electrode and a second electrode located at both sides of the light-emitting functional layer in a direction perpendicular to the base substrate, the first electrode is located between the light-emitting functional layer and the base substrate, and the light-emitting functional layer includes a plurality of film layers. The display substrate further includes a defining structure, and at least one defining structure is disposed between at least two adjacent sub-pixels; a first orthographic projection of a surface, close to the base substrate, of the defining structure between adjacent sub-pixels on the base substrate is completely located within a second orthographic projection of a surface, away from the base substrate, of the defining structure on the base substrate; in an arrangement direction of light-emitting regions of the adjacent sub-pixels, a maximum size of the second orthographic projection is greater than a maximum size of the first orthographic projection, and a material of the defining structure includes an inorganic nonmetallic material; in at least a partial region of the first region, at least one film layer in the light-emitting functional layer is disconnected at an edge of the defining structure, and second electrodes of adjacent sub-pixels are at least partially continuously arranged. The defining structure disposed in the display substrate provided by the present disclosure realizes the continuous arrangement of the second electrode while isolating at least one film layer in the light-emitting functional layer, which can reduce the crosstalk between adjacent sub-pixels and avoid the problem of brightness uniformity caused by a large-area fracture of the second electrode.

An embodiment of the present disclosure provides a display substrate, which includes a base substrate and a plurality of sub-pixels located on the base substrate. The base substrate at least includes a first region; the plurality of sub-pixels is located in a first region of the base substrate, each sub-pixel in at least some sub-pixels includes a light-emitting element, the light-emitting element includes a light-emitting functional layer and a first electrode and a second electrode located at both sides of the light-emitting functional layer in a direction perpendicular to the base substrate, the first electrode is located between the light-emitting functional layer and the base substrate, and the light-emitting functional layer includes a plurality of film layers. The display substrate further includes a defining structure, at least one defining structure is disposed between at least two adjacent sub-pixels, the plurality of sub-pixels includes a first sub-pixel, a second sub-pixel and a third sub-pixel, the second sub-pixel and the third sub-pixel are adjacent to the first sub-pixel, a maximum size of the defining structure disposed between the first sub-pixel and the second sub-pixel in an arrangement direction of these two sub-pixels is a first size, a maximum size of the defining structure disposed between the first sub-pixel and the third sub-pixel in an arrangement direction of these two sub-pixels is a second size, and the first size is different from the second size. In the embodiment of the present disclosure, by setting the sizes of the defining structures disposed between different adjacent sub-pixels, the matching of the arrangement relationship between the defining structures and the sub-pixels can be improved, and the conduction effect of the second electrode can be improved.

The display substrate, the manufacturing method thereof and the display device provided by the embodiments of the present disclosure are described below with reference to the accompanying drawings.

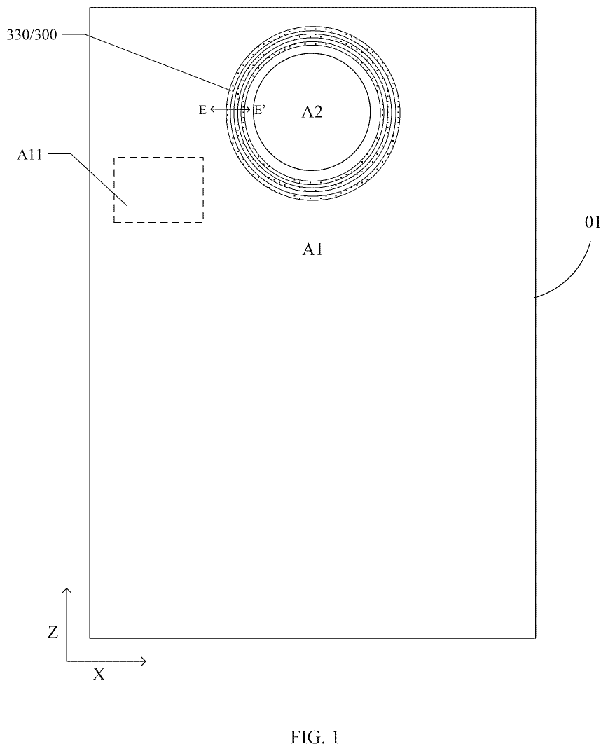

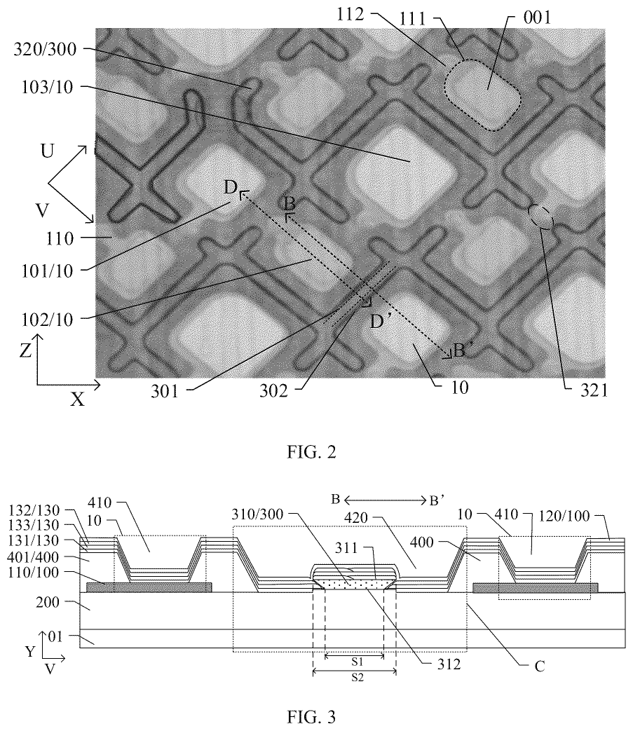

FIG. 1 is a planar view of a display substrate provided by an embodiment of the present disclosure, FIG. 2 is a schematic diagram of a defining structure and sub-pixels in a partial region A11 as shown in FIG. 1, and FIG. 3 is a partial cross-sectional structural view taken along line BB′ as shown in FIG. 2. As shown in FIGS. 1-3, the display substrate includes a base substrate 01, and the base substrate 01 at least includes a first region A1.

As shown in FIGS. 1-3, the display substrate includes a plurality of sub-pixels 10 located on the base substrate 01, and the plurality of sub-pixels 10 are located in the first region A1. Each sub-pixel 10 in at least some sub-pixels 10 includes a light-emitting element 100, the light-emitting element 100 includes a light-emitting functional layer 130 and a first electrode 110 and a second electrode 120 located at both sides of the light-emitting functional layer 130 along a direction perpendicular to the base substrate 01, the first electrode 110 is located between the light-emitting functional layer 130 and the base substrate 01, and the light-emitting functional layer 130 includes a plurality of layers. For example, the light-emitting functional layer 130 includes a charge generation layer 133. For example, the light-emitting element 100 may be an organic light-emitting element. For example, each sub-pixel located in the display region includes a light-emitting element.

As shown in FIGS. 1-3, the display substrate further includes a defining structure 300, and at least one defining structure 300 is disposed between at least two adjacent sub-pixels 10. A first orthographic projection 301 of a surface, close to the base substrate 01, of the defining structure 300 between adjacent sub-pixels 10 on the base substrate 01 is completely located within a second orthographic projection 302 of a surface, away from the base substrate 01, of the defining structure 300 on the base substrate 01; in an arrangement direction of light-emitting regions of the adjacent sub-pixels 10, a maximum size S2 of the second orthographic projection is greater than a maximum size S1 of the first orthographic projection. The arrangement direction of the light-emitting regions of the adjacent sub-pixels mentioned above can be a direction parallel to the center connecting line of the sub-pixels 10, such as the V direction, the U direction, the X direction or the Z direction as shown in FIG. 2. For example, the defining structure 300 is disposed between any adjacent sub-pixels 10.

As shown in FIGS. 1-3, the defining structure 300 includes an inorganic nonmetallic material. For example, the material of the defining structure 300 can include any one or more of silicon oxide (SiOx), silicon nitride (SiNx) and silicon oxynitride (SiON).

As shown in FIGS. 1-3, in at least a partial region of the first region A1, at least one film layer in the light-emitting functional layer 130 is disconnected at the edge of the defining structure 300, and the second electrodes 120 are continuously arranged at the edge of the defining structure 300.

In the display substrate provided by the present disclosure, while the edge of the defined structure isolates at least one film layer in the light-emitting functional layer, the second electrodes at the edge of the defining structure are continuously arranged, which can reduce the crosstalk between adjacent sub-pixels and avoid the problem of brightness uniformity caused by a large-area fracture of the second electrode. For example, if the second electrode in the display region has a large-area fracture, the voltage drop of the VSS signal is increased, and the problem of brightness uniformity occurs.

The defining structure mentioned above can refer to a structure for defining the distribution of at least one film layer in the light-emitting functional layer; and for example, at least one film layer in the light-emitting functional layer is disconnected at the edge of the defining structure, and the second electrodes are continuously arranged at the edge of the defining structure.

The term “adjacent sub-pixels” in any embodiment of the present disclosure means that no any other sub-pixel 10 is disposed between the two sub-pixels 10.

For example, as shown in FIG. 3, the light-emitting functional layer 130 can include a first light-emitting layer (EML) 131, a charge generation layer (CGL) 133 and a second light-emitting layer (EML) 132 which are stacked, and the charge generation layer 133 is located between the first light-emitting layer 131 and the second light-emitting layer 132. The charge generation layer has a relatively high conductivity, which can make the light-emitting functional layer have the advantages of long operation life, low power consumption and being able to achieve high brightness. For example, compared with a light-emitting functional layer without the charge generation layer, the sub-pixel can nearly double the illumination brightness by setting the charge generation layer in the light-emitting functional layer.

For example, the light-emitting element 100 of the same sub-pixel 10 can be a tandem light-emitting element, such as a Tandem OLED.

For example, the charge generation layer 133 can include an N-type charge generation layer and a P-type charge generation layer.

For example, in each sub-pixel 10, the light-emitting functional layer 130 can further include a hole injection layer (HIL), a hole transport layer (HTL), an electron transport layer (ETL) and an electron injection layer (EIL).

For example, the hole injection layer, the hole transport layer, the electron transport layer, the electron injection layer and the charge generation layer 133 are all common film layers of the plurality of sub-pixels 10, which can be called common layers. For example, at least one film layer, which is disconnected at the edge of the defining structure 300, in the light-emitting functional layers 130 can be at least one film layer of the common layers mentioned above. By disconnecting at least one film layer of the common layers at the edge of the defining structure 300 between adjacent sub-pixels, the probability of crosstalk between adjacent sub-pixels can be reduced. For example, the common layers and the second electrodes can be film layers formed by using an open mask.

For example, the second light-emitting layer 132 can be located between the first light-emitting layer 131 and the second electrode 120, and the hole injection layer can be located between the first electrode 110 and the first light-emitting layer 131. For example, an electron transport layer can be disposed between the charge generation layer 133 and the first light-emitting layer 131. For example, a hole transport layer can be disposed between the second light-emitting layer 132 and the charge generation layer 133. For example, an electron transport layer and an electron injection layer can be disposed between the second light-emitting layer 132 and the second electrode 120.

For example, in the same sub-pixel 10, the first light-emitting layer 131 and the second light-emitting layer 132 can be light-emitting layers which emit light of the same color. For example, the first light-emitting layers 131 in the sub-pixels 10 that emit light of different colors emit light of different colors. Of course, the embodiment of the present disclosure is not limited thereto. For example, the second light-emitting layer 132 in the sub-pixel 10 that emits light of different colors emits light of different colors. Of course, the embodiment of the present disclosure is not limited to this. For example, in the same sub-pixel 10, the first light-emitting layer 131 and the second light-emitting layer 132 can be light-emitting layers which emit light of different colors; by setting the light-emitting layers which emit light of different colors in the same sub-pixel 10, the light emitted by the multi-layer light-emitting layers included in the sub-pixel 10 can be mixed into white light, and the color of the emergent light of each sub-pixel can be adjusted by setting a color filter layer.

For example, as shown in FIGS. 1-3, the first light-emitting layers 131 of adjacent sub-pixels 10 can overlap with each other on the defining structure 300. For example, the second light-emitting layers 132 of adjacent sub-pixels 10 can overlap with each other on the defining structure 300. But not limited thereto, for example, the first light-emitting layers 131 of adjacent sub-pixels 10 can be arranged at intervals on the defining structure 300, and the second light-emitting layers 132 of adjacent sub-pixels 10 can be arranged at intervals on the defining structure 300; alternatively, the first light-emitting layer 131 of only one sub-pixel 10 of adjacent sub-pixels 10 may be disposed on the defining structure 300, and the second light-emitting layer 132 of only one sub-pixel 10 of adjacent sub-pixels 10 may be disposed on the defining structure 300.

For example, in adjacent sub-pixels 10, the light-emitting layers located at a same side of the charge generation layer 133 can be arranged at intervals from each other, or can be overlapped or connected with each other at the gap between two sub-pixels 10. without being limited in the embodiment of the present disclosure.

For example, the material of the electron transport layer can include aromatic heterocyclic compounds, such as benzimidazole derivatives, imidazole pyridine derivatives, benzimidazole phenanthroline derivatives, or other imidazole derivatives; pyrimidine derivatives, triazine derivatives, or other zine derivatives; quinoline derivatives, isoquinoline derivatives, phenanthroline derivatives, or other compounds containing nitrogen-containing six-membered ring structures (also including compounds with phosphine oxide substituents on heterocyclic rings).

For example, the material of the charge generation layer 133 can be a material containing phosphorus oxide groups or a material containing triazine.

For example, the ratio of the electron mobility the material of the charge generation layer 133 to the electron mobility of the electron transport layer is in the range of 10⁻²˜10².

For example, as shown in FIG. 3, at least one film layer in the light-emitting functional layers 130 can be a charge generation layer 133, a first charge generation layer orthographic projection of the charge generation layer 133 on the base substrate 01 is continuous, and the second charge generation layer orthographic projection of the charge generation layer 133 on the plane perpendicular to the base substrate 01 is discontinuous. For example, the charge generation layer 133 can include a portion located on the defining structure 300 and a portion not located on the defining structure 300, and these two portions are disconnected at the edge of the defining structure 300. For example, the first charge generation layer orthographic projections of these two portions on the base substrate 01 can be connected or overlapped, and the first charge generation layer orthographic projections are continuous. For example, these two portions have different distances from the base substrate 01, the second charge generation layer orthographic projections of these two portions on the plane perpendicular to the base substrate (the plane where line BB′ and the Y direction are located) are discontinuous.

For example, as shown in FIG. 3, the light-emitting functional layer 130 includes at least one light-emitting layer, and at least one light-emitting layer and at least one other film layer are included in the film layers which are disconnected at the position of the defining structure 300; the area of the orthographic projection of the disconnected at least one other film layer on the base substrate 01 is greater than the area of the orthographic projection of the disconnected at least one light-emitting layer on the base substrate 01; or the area of the part, covering the defining structure 300, of the disconnected at least one other film layer is greater than the area of the part, covering the defining structure 300, of the disconnected at least one light-emitting layer.

For example, as shown in FIG. 3, the second electrodes 120 in the plurality of sub-pixels 10 can be a common electrode shared by the plurality of sub-pixels, and the second electrode 120 is a whole-layer film layer in the case where no defining structure 300 is disposed between two adjacent sub-pixels 10.

For example, as shown in FIG. 3, the orthographic projections of the second electrode 120 and at least one of the plurality of film layers included in the light-emitting functional layer 130 on the base substrate 01 overlap with the orthographic projection of the defining structure 300 on the base substrate 01.

For example, at least a part of one of the plurality of film layers included in the light-emitting functional layer 130 covers a part of the side surface of the defining structure 300.

For example, the thickness of a part of the second electrode 120 overlapping with the defining structure 300 in the direction perpendicular to the base substrate 01 is less than the thickness of at least a part of the second electrode 120 not overlapping with the defining structure 300, and the thickness of a part of the charge generation layer 133 overlapping with the defining structure 300 in the direction perpendicular to the base substrate 01 is less than the thickness of at least a part of the charge generation layer 133 not overlapping with the defining structure 300.

For example, the thickness of a part of the second electrode 120 at the center of the defining structure 300 is greater than the thickness of a part of the second electrode 200 at the edge of the defining structure 300, and the thickness of a part of the charge generation layer 133 at the center of the defining structure 300 is greater than the thickness of a part of the charge generation layer 133 at the edge of the defining structure 300. For example, the thickness of the middle part of the second electrode 120 on the defining structure 300 is greater than the thickness of the margin part of the second electrode 120. For example, the thickness of the middle part of the charge generation layer 133 on the defining structure 300 is greater than the thickness of the margin part of the charge generation layer 133.

For example, FIG. 3 illustratively shows that all the film layers included in the light-emitting functional layer 130 are disconnected at the edge of the defining structure 300, and the second electrode 120 is not disconnected at the edge of the defining structure 300. But not limited thereto, in some other examples, the thickness of the defining structure can be set, so that some film layers in the light-emitting functional layer and close to the base substrate are disconnected at the edge of the defining structure, and some film layers in the light-emitting functional layer and away from the base substrate are not disconnected at the edge of the defining structure. For example, the film layers at one side of the charge generation layer away from the base substrate are not disconnected, the charge generation layer and the film layers at one side of the charge generation layer close to the base substrate are disconnected, and the second electrode is not disconnected at the edge of the defining structure.

For example, the first electrode 110 can be an anode, and the second electrode 120 can be a cathode. For example, the cathode can be made of a material with high conductivity and low work function, and for example, the cathode can be made of a metal material. For example, the anode can be formed of a transparent conductive material with high work function.

For example, as shown in FIG. 2, the shapes of the first orthographic projection 301 and the second orthographic projection 302 can be the same. For example, along the direction parallel to line BB′, the ratio of the distance between a first edge of one side of the first orthographic projection 301 and a second edge of the second orthographic projection 302 which is closer to this first edge to the distance between a first edge of the other side of the first orthographic projection 301 and a second edge of the second orthographic projection 302 which is closer to this first edge can be in the range of 0.7-1.5. For example, the ratio of the distances between the two first edges and the corresponding two second edges can be in the range of 0.8-1.3. For example, the ratio of the distances between the two first edges and the corresponding two second edges can be in the range of 0.9-1.4. For example, the ratio of the distances between the two first edges and the corresponding two second edges can be in the range of 0.95-1.2. For example, the ratio of the distances between the two first edges and the corresponding two second edges can be in the range of 1-1.1.

In some examples, as shown in FIG. 3, the cross-sectional shape of the defining structure 300 cut by the plane where the center connecting line of the adjacent sub-pixels is located includes a first trapezoid 310. The length of a first base 311 of the first trapezoid 310 away from the base substrate 01 is greater than the length of a second base 312 of the first trapezoid 310 close to the base substrate 01, and the plane is perpendicular to the base substrate 01, and for example, the plane is the VY plane shown in FIG. 3. But not limited thereto, the plane can also be the UY plane, the XY plane, etc.

In some examples, as shown in FIG. 3, the thickness of the defining structure 300 is in the range of 300-550 angstroms. For example, the thickness of the defining structure 300 is in the range of 320-530 angstroms. For example, the thickness of the defining structure 300 is in the range of 350-400 angstroms. For example, the thickness of the defining structure 300 is in the range of 330-420 angstroms. For example, the thickness of the defining structure 300 is in the range of 360-450 angstroms. For example, the thickness of the defining structure 300 is in the range of 380-500 angstroms. For example, the thickness of the defining structure 300 is in the range of 480-520 angstroms.

For example, as shown in FIG. 3, in the direction perpendicular to the base substrate 01, the ratio of the thickness of the defining structure 300 to the thickness of the light-emitting functional layer 130 is in the range of 0.7-1.5. For example, the ratio of the thickness of the defining structure 300 to the thickness of the light-emitting functional layer 130 is in the range of 0.8-1.2. For example, the ratio of the thickness of the defining structure 300 to the thickness of the light-emitting functional layer 130 is in the range of 0.9-1.1.

In some examples, as shown in FIG. 3, the included angle between the second base 312 and the leg of the first trapezoid 310 is in the range of 110-150 degrees. For example, the included angle between the second base 312 and the leg of the first trapezoid 310 is in the range of 115-130 degrees. For example, the included angle between the second base 312 and the leg of the first trapezoid 310 is in the range of 112-140 degrees. For example, the included angle between the second base 312 and the leg of the first trapezoid 310 is in the range of 120-148 degrees. For example, the included angle between the second base 312 and the leg of the first trapezoid 310 is in the range of 118-135 degrees. For example, the included angle between the second base 312 and the leg of the first trapezoid 310 is in the range of 122-145 degrees. For example, the included angle between the second base 312 and the leg of the first trapezoid 310 is in the range of 135-146 degrees.

For example, the ratio of the lengths of the two legs of the first trapezoid 310 is in the range of 0.9-1.1. For example, the lengths of the two legs of the first trapezoid 310 are the same.

For example, as shown in FIG. 3, the first base 311 is a cross-sectional line, cut by the VY plane, of the surface of the defining structure 300 away from the base substrate 01; the second base 312 is a cross-sectional line, cut by the VY plane, of the surface of the defining structure 200 facing the base substrate 01; and the legs are cross-sectional lines, cut by the VY plane, of the sidewall of the defining structure 300. For example, the sidewall of the defining structure 300 is an inclined sidewall, which inclines to a side away from the center of the defining structure.

The first trapezoid in the embodiment of the present disclosure includes a standard trapezoid or an approximate trapezoid; the legs, the first base and the second base of the standard trapezoid are straight edges; and at least one of the legs, the first base and the second base of the approximate trapezoid is a curved edge. For example, in the case where a leg of the first trapezoid is a curved edge, the curved edge can bend towards the midpoint of the first base or can bend away from the midpoint of the first base. In the case where the first trapezoid is an approximate trapezoid, the included angle between the leg and the second base can be an included angle between a straight line parallel to the base substrate and a connecting line between the intersection point of the leg and the second base and the intersection point of the leg and the first base.

In the display substrate provided by the present disclosure, by setting the shape, thickness and sidewall inclination angle of the defining structure, at least one film layer in the light-emitting functional layer is partitioned, and at the same time, the continuous arrangement of the second electrode is realized, which is helpful to reduce the crosstalk generated between adjacent sub-pixels and avoid the problem of brightness uniformity caused by the fracture of the second electrode.

In some examples, as shown in FIG. 3, the display substrate further includes a first insulating layer 200 located between the defining structure 300 and the base substrate 01. In at least the partial region of the first region A1, the first insulating layer 200 is in contact with the surface of the defining structure 300 facing the base substrate 01, the first insulating layer 200 is located between the first electrode 110 and the base substrate 01, and the material of the first insulating layer 200 includes an organic material.

For example, as shown in FIG. 3, the first insulating layer 200 includes a planarization (PLN) layer.

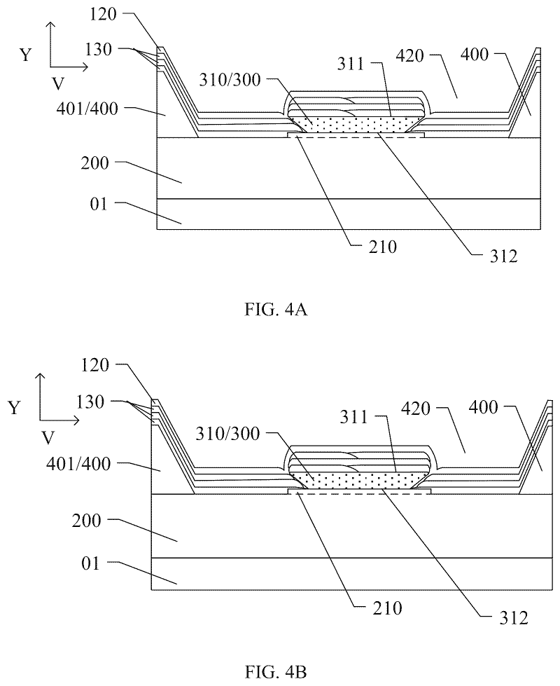

FIG. 4A is an enlarged view of the region C as shown in FIG. 3. In some examples, as shown in FIGS. 3 and 4A, the first insulating layer 200 includes a protrusion 210 in contact with the surface of the defining structure 300, and the first orthographic projection of the defining structure 300 is completely within the orthographic projection of the protrusion 210 on the base substrate 01.

FIG. 4B is an enlarged view of the region C as shown in FIG. 3 according to a different example. The defining structure 300 shown in FIG. 4B is different from the defining structure 300 shown in FIG. 4A in that the edge of the defining structure 300 shown in FIG. 4B is rounded.

For example, as shown in FIGS. 3 and 4A, the protrusion 210 included in the first insulating layer 200 is only located below the defining structure 300, and no protrusion 210 is provided at other positions. For example, the protrusion is not provided at the position of the light-emitting region of the light-emitting element; for example, the protrusion is not provided at the position of the first electrode of the light-emitting element; for example, the protrusion is not provided at the position of the pixel defining portion of the pixel defining pattern (described later).

For example, as shown in FIGS. 3 and 4A, the maximum size of the surface, close to the base substrate 01, of the defining structure 300 in a direction parallel to the base substrate 01 is less than the maximum size of the protrusion 210 in this direction. For example, the length of the second base 312 of the defining structure 300 is less than the size of the protrusion 210 in a direction parallel to the second base 312.

For example, as shown in FIGS. 3 and 4A, the ratio of the sizes of two gaps between two ends of the second base 312 and two ends of the protrusion 210 can be in the range of 0.8-1.2, or in the range of 0.9-1.1, or 1. For example, the second base 312 can be located in a middle region of the protrusion 210.

In some examples, as shown in FIGS. 3 and 4A, an edge of the protrusion 210 is flush with an edge of a surface, away from the base substrate 01, of the defining structure 300. For example, a straight line extending along the direction perpendicular to the base substrate 01 passes through the edge of the protrusion 210 and the edge of the surface, away from the base substrate 01, of the defining structure 300. For example, the second orthographic projection completely coincides with the orthographic projection of the protrusion 210 on the base substrate 01.

For example, as shown in FIGS. 3 and 4A, the thickness of the protrusion 210 can be in the range of 200-550 angstroms. For example, the thickness of the protrusion 210 can be less than the thickness of the defining structure 300.

For example, as shown in FIGS. 3 and 4A, the light-emitting functional layer 113 covers the sidewall of the protrusion 210. For example, the light-emitting functional layer 113 covers the surface of the protrusion 210 away from the base substrate 01.

For example, the process can be adjusted to make the thickness of the protrusion 210 as small as possible during the formation of the defining structure 300.

For example, as shown in FIGS. 3 and 4A, the shape of the cross-section of the protrusion 210 cut by the VY plane perpendicular to the base substrate 01 can be a rectangle.

In some examples, as shown in FIG. 3, a surface of the first electrode 110 is in contact with a surface of the first insulating layer 200, and the distance between the surface of the first electrode 110 away from the base substrate 01 and the base substrate 01 is less than the distance between the surface of the defining structure 300 away from the base substrate 01 and the base substrate 01.

For example, as shown in FIG. 3, the defining structure 300 and the first electrode 110 are both located on the first insulating layer 200, and the defining structure 300 and the first electrode 110 are arranged at intervals.

In some examples, as shown in FIGS. 1-3, the display substrate further includes a pixel defining pattern 400 located at one side of the first electrode 110 away from the base substrate 01, at least the pixel defining pattern 400 located in the first region A1 includes a plurality of first openings 410, one sub-pixel 10 corresponds to at least one first opening 410, the light-emitting element 100 of the sub-pixel 10 is at least partially located in the first opening 410 corresponding to the sub-pixel 10, and the first opening 410 is configured to expose the first electrode 110. For example, the first opening 410 exposes a part of the first electrode 110. For example, one sub-pixel 10 can correspond to one first opening 410.

For example, as shown in FIG. 3, in the case where the light-emitting functional layer 130 is formed in the first opening 410 of the pixel defining pattern 400, the first electrode 110 and the second electrode 120 located at both sides of the light-emitting functional layer 130 can drive the light-emitting functional layer 130 in the first opening 410 to emit light. For example, the light-emitting region can refer to the region where the sub-pixel effectively emits light, and the shape of the light-emitting region refers to a two-dimensional shape; for example, the shape of the light-emitting region can be the same as the shape of the first opening 410 of the pixel defining pattern 400.

For example, as shown in FIG. 3, the pixel defining pattern 400 includes a pixel defining portion 401 surrounding the first opening 410, and the material of the pixel defining portion 401 can include polyimide, acrylic or polyethylene terephthalate, etc.

In some examples, as shown in FIG. 3, the pixel defining pattern 400 further includes a second opening 420, and at least part of the defining structure 300 is exposed by the second opening 420. For example, the defining structure 300 is located in the second opening 420, and for example, the defining structure 300 is completely exposed by the second opening 420. For example, a gap is provided between the defining structure 300 and the pixel defining portion 401 of the pixel defining pattern 400.

In some examples, as shown in FIG. 3, at least one film layer in the light-emitting functional layer 130 is disconnected at at least part of an edge of the defining structure 300 exposed by the second opening 420, and the second electrode 120 is continuously arranged at this edge.

For example, as shown in FIG. 3, along the V direction, the size of the first opening 410 can be less than the size of the second opening 420. But not limited thereto, the size of the second opening can be set according to the needs of the product.

For example, as shown in FIG. 3, in the direction perpendicular to the base substrate 01, the thickness of the defining structure 300 is less than the thickness of the pixel defining portion 401.

For example, as shown in FIGS. 3 and 4A, at least part of the protrusion 210 is located in the second opening 420. For example, the protrusion 210 is completely located in the second opening 420.

For example, a spacer can also be provided at one side of the pixel defining portion 401 of the pixel defining pattern 400 away from the base substrate 01, and the spacer is configured to support an evaporation mask plate for manufacturing a light-emitting layer.

For example, FIGS. 3-4A illustratively show that one defining structure 300 is disposed between adjacent sub-pixels 10, but it is not limited thereto. Two or more defining structures can be disposed between adjacent sub-pixels 10, and the number of defining structures can be set according to the distance between adjacent sub-pixels and the size of the defining structure.

For example, one defining structure 300 is disposed between two adjacent sub-pixels 10, and the ratio of the distances between the defining structure 300 and the light-emitting regions of the two sub-pixels 10 can be in the range of 0.8-1.1, or in the range of 0.9-1.

For example, a spacer and a thin film encapsulation layer can be provided at one side of the pixel defining pattern 400 away from the base substrate 01. For example, a color filter layer can be further provided at one side of the pixel defining pattern 400 away from the base substrate 01.

FIG. 5 is a partial cross-sectional structural view of a display substrate provided by another example of the embodiment of the present disclosure. The display substrate shown in FIG. 5 is different from the display substrate shown in FIGS. 3-4A in that the second opening 420 shown in FIG. 5 only exposes a part of the defining structure 300, the part of the defining structure 300 is covered by the pixel defining portion 401, the edge of a part of the defining structure 300 exposed by the second opening 420 is configured to isolate at least one film layer in the light-emitting functional layer 130, and the second electrode 120 is continuously arranged at the edge of the defining structure 300 exposed by the second opening 420.

For example, a plurality of defining structures can be disposed between adjacent sub-pixels, and at least one defining structure is exposed by the second opening. For example, a part of at least one defining structure is covered by the pixel defining portion.

In some examples, as shown in FIG. 2, the plurality of sub-pixels 10 includes a plurality of first color sub-pixels 101, a plurality of second color sub-pixels 102, and a plurality of third color sub-pixels 103. For example, one of the first color sub-pixel 101 and the third color sub-pixel 103 emits red light, and the other of the first color sub-pixel 101 and the third color sub-pixel 103 emits blue light; the second color sub-pixel 102 emits green light. FIG. 2 illustratively shows that the first color sub-pixel 101 emits red light and is a red sub-pixel; the third color sub-pixel 103 emits blue light and is a blue sub-pixel; and the second color sub-pixel 102 emits green light and is a green sub-pixel.

For example, as shown in FIG. 2, the plurality of first color sub-pixels 101 and the plurality of third color sub-pixels 103 are alternately arranged along the X direction and the Z direction parallel to the base substrate 01 to form a plurality of first pixel rows and a plurality of first pixel columns, and the plurality of second color sub-pixels 102 are arrayed along the X direction and the Z direction to form a plurality of second pixel rows and a plurality of second pixel columns, the plurality of first pixel rows and the plurality of second pixel rows are alternately arranged along the Z direction and offset with respect to each other in the X direction, and the plurality of first pixel columns and the plurality of second pixel columns are alternately arranged along the X direction and offset with respect to each other in the Z direction.

In some examples, as shown in FIG. 2, the defining structure 300 includes a plurality of first annular defining structures 320, and the first annular defining structures 320 surround at least one sub-pixel 10 among the plurality of first color sub-pixels 101, the plurality of second color sub-pixels 102 and the plurality of third color sub-pixels 103.

For example, as shown in FIG. 2, each sub-pixel 10 of sub-pixels 10 of at least one color among the first color sub-pixels 101, the second color sub-pixels 102 and the third color sub-pixels 103 is surrounded by the first annular defining structures 320.

For example, as shown in FIG. 2, the sub-pixels 10 arranged along the V direction can share a part of the first annular defining structures 320. For example, the sub-pixels 10 arranged along the U direction can share a part of the first annular defining structures 320.

For example, as shown in FIG. 2, two first annular defining structures 320 corresponding to two adjacent sub-pixels 10 arranged along the X direction can be an integrated structure or can be arranged at intervals. For example, two first annular defining structures 320 corresponding to two adjacent sub-pixels 10 arranged along the Z direction can be an integrated structure or can be arranged at intervals.

For example, at least one first annular defining structure 320 can be a closed annular structure. For example, at least one first annular defining structure 320 can be a non-closed annular structure. For example, some of the first annular defining structures 320 can be closed annular structures, and some other of the first annular defining structures 320 can be non-closed annular structure. For example, all the first annular defining structures 320 can be closed annular structures. For example, all the first annular defining structures 320 can be non-closed annular structures.

For example, the first annular defining structure 320 having a non-closed annular structure can include at least one notch 321. For example, the first annular defining structure 320 can include one notch 321, or two notches 321, or three notches 321. For example, different first annular defining structures 320 can include the same number of notches 321 or different numbers of notches 321.

For example, as shown in FIG. 2, at least part of the boundary of the defining structure 300 and the boundary of the light-emitting region of the sub-pixel 10 immediately adjacent thereto have approximately the same contour. For example, the boundary contour of the light-emitting region of the sub-pixel 10 can include a plurality of straight edges and/or arc edges connecting adjacent straight edges, and the boundary contour of the defining structure 300 surrounding the light-emitting region can include straight edge contours corresponding to the straight edges of the light-emitting region and/or arc edge contours corresponding to the arc edges of the light-emitting region.

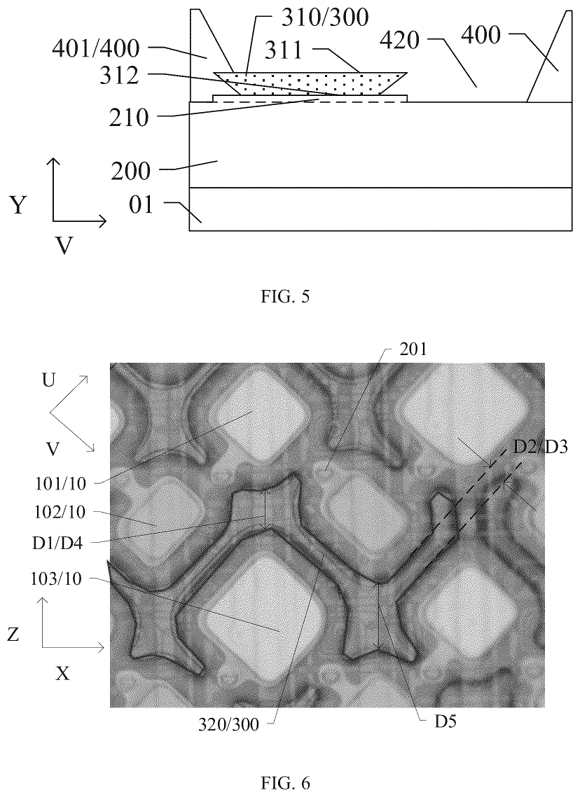

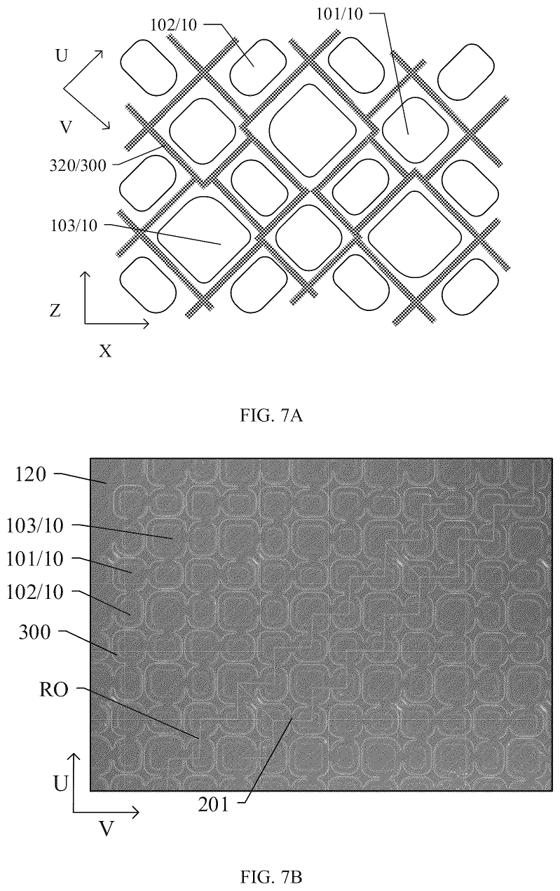

FIGS. 6 and 7A are partial planar structural views of a display substrate provided by different examples of the embodiment of the present disclosure. The display substrate shown in FIGS. 6 and 7A is different from the display substrate shown in FIG. 2 in that the shape of the defining structure 300 is different; for example, the planar shape is different, and for example, the width of the defining structure is different. The planar shape and width of the defining structure and the opening surrounded by the first annular defining structure can be flexibly set according to the size of the light-emitting region of the sub-pixel and the distance between the light-emitting regions of adjacent sub-pixels.

For example, the distance between the defining structure 300 and the light-emitting region of the sub-pixel 10 adjacent thereto as shown in FIG. 6 is different from the distance between the defining structure and the light-emitting region of the sub-pixel 10 adjacent thereto as shown in FIG. 2. For example, the length of the upper base of the first trapezoidal cross-section of the defining structure 300 shown in FIG. 6 is different from the length of the upper base of the first trapezoidal cross-section of the defining structure 300 shown in FIG. 2.

For example, as shown in FIG. 6, the size of the portion of the defining structure 300 between adjacent sub-pixels 10 arranged along the X direction or the Z direction is relatively large. For example, as shown in FIG. 7A, at least one first annular defining structure 320 is a closed annular structure.

For example, as shown in FIGS. 2 and 6, in the direction perpendicular to the base substrate 01, a part of the first electrode 110 overlaps with the notch 321 of the first annular defining structure 320. For example, one first annular defining structure 320 includes at least two notches 321, and these notches 321 overlap with the first electrodes 110 of different sub-pixels 10.

For example, the orthographic projection of a part of the first electrode 110 on the base substrate is inserted into the notch of the orthographic projection of the first annular defining structure 320 on the base substrate. For example, in the direction perpendicular to the base substrate, the first annular defining structure 320 does not overlap with the connection electrode.

In the display substrate provided by an example of the present disclosure, by setting the notch in the first annular defining structure to bypass the first electrode, it can prevent the first annular defining structure from interfering with the position of the first electrode of the light-emitting element.

For example, as shown in FIG. 7A, the edge position of the defining structure 300 is only used to disconnect at least some film layers in the light-emitting functional layer of the light-emitting element without disconnecting the second electrode of the light-emitting element, and at least one first annular defining structure 320 is set as a closed annular structure surrounding the sub-pixel 10, which is helpful to completely disconnecting the charge generation layers in different sub-pixels 10 to avoid crosstalk between adjacent sub-pixels, while realizing the continuity of the second electrode to improve the display uniformity.

In the display substrate provided by the present disclosure, by setting the position and size of the first annular defining structure, the closed annular structure is adopted while bypassing the first electrode, thereby reducing the crosstalk between adjacent sub-pixels and avoiding the problem of brightness uniformity caused by the fracture of the second electrode.

In some examples, as shown in FIGS. 2, 3, 6 and 7B, the second electrode 120 of at least one sub-pixel 10 and the second electrode 120 of one sub-pixel 10 adjacent thereto in a first sub-direction (e.g., one of the row direction and the column direction, e.g., one of the third direction and the fourth direction) are continuously arranged, the second electrode 120 of the at least one sub-pixel 10 and the second electrode 120 of one sub-pixel 10 adjacent thereto in a second sub-direction (e.g., the other of the row direction and the column direction, e.g., the other of the third direction and the fourth direction) are disconnected, and the first sub-direction is intersected with the second sub-direction.

In some examples, as shown in FIGS. 2, 3, 6 and 7B, the second electrode 120 of at least one sub-pixel 10 and the second electrode 120 of one sub-pixel 10 adjacent thereto in a first sub-direction are continuously arranged, the second electrode 120 of the at least one sub-pixel 10 and the second electrode 120 of one sub-pixel 10 adjacent thereto in a second sub-direction are disconnected, and the first sub-direction is intersected with the second sub-direction.

For example, as shown in FIGS. 2, 3, 6 and 7B, the second electrode 120 of any sub-pixel 10 and the second electrode 120 of one sub-pixel 10 adjacent thereto in any direction can be continuously arranged, so as to improve the conduction effect of the second electrode. For example, the second electrode 120 of any sub-pixel 10 and the second electrode 120 of one sub-pixel 10 adjacent thereto in at least one direction can be continuously arranged, so as to at least ensure the conductivity of the second electrode of the sub-pixel.

In some examples, as shown in FIGS. 2, 3, 6 and 7B, the defining structure 300 surrounds more than 50% of the outline of at least one sub-pixel 10.

For example, the defining structure 300 surrounds more than 55% of the outline of at least one sub-pixel 10. For example, the defining structure 300 surrounds more than 60% of the outline of at least one sub-pixel 10. For example, the defining structure 300 surrounds more than 65% of the outline of at least one sub-pixel 10. For example, the defining structure 300 surrounds more than 70% of the outline of at least one sub-pixel 10. For example, the defining structure 300 surrounds more than 75% of the outline of at least one sub-pixel 10. For example, the defining structure 300 surrounds more than 80% of the outline of at least one sub-pixel 10. For example, the defining structure 300 surrounds more than 85% of the outline of at least one sub-pixel 10. For example, the defining structure 300 surrounds more than 90% of the outline of at least one sub-pixel 10. For example, the defining structure 300 surrounds more than 95% of the outline of at least one sub-pixel 10.

In some examples, as shown in FIGS. 2, 3, 6 and 7B, the second electrode 120 of at least one sub-pixel 10 and the second electrode 120 of one sub-pixel 10 adjacent thereto are continuously arranged, and the minimum width of the second electrode 120 between these two adjacent sub-pixels 10 is greater than 1 micron in the direction perpendicular to the arrangement direction of these two adjacent sub-pixels. For example, the minimum width can be greater than 2 microns. For example, the minimum width can be greater than 3 microns. For example, the minimum width can be greater than 4 microns. For example, the minimum width can be greater than 5 microns. For example, the minimum width can be greater than 6 microns. For example, the minimum width can be greater than 7 microns. For example, the minimum width can be greater than 8 microns. For example, the minimum width can be greater than 9 microns. For example, the minimum width can be greater than 10 microns.

For example, as shown in FIG. 6, the first size D1 is greater than 1 micron. For example, as shown in FIG. 6, D5 is greater than 1 micron.

In some examples, as shown in FIGS. 2, 3, 6 and 7B, the orthographic projection of a center connecting line of these two adjacent sub-pixels 10 on the plane where the second electrode 120 is located is within the second electrode 120.

For example, the orthographic projection of the center connecting line on the base substrate is located within the orthographic projection of the second electrode 120 on the base substrate, and the second electrode 120 at the position where the center connecting line is located is continuously arranged.

In some examples, as shown in FIGS. 2, 6 and 7B, the outlines of at least part of the defining structures 300 are the same as the outlines of the light-emitting regions of the sub-pixels 10 surrounded by the at least part of the defining structures 300, and the ratio of the distances between adjacent edges of different defining structures 300 and corresponding light-emitting regions of the sub-pixels 10 surrounded by the different defining structures 300 is in the range of 0.9-1.1. For example, the distances are the same.

For example, the distance can be in the range of 7-10 microns. For example, the distance can be in the range of 8-9 microns.

For example, the ratio of the distances between adjacent edges of a defining structure and the light-emitting region of the sub-pixel surrounded by the same defining structure at different positions is in the range of 0.9-1.1. For example, the distances between adjacent edges of a defining structure and the light-emitting region of the sub-pixel surrounded by the same defining structure are equal at different positions.

FIG. 8 is a partial cross-sectional structural view taken along line DD′ as shown in FIG. 2. In some examples, as shown in FIGS. 2 and 8, each sub-pixel 10 in at least part of the plurality of sub-pixels 10 further includes a pixel circuit 140, the first electrode 110 of the light-emitting element 100 of at least one sub-pixel 10 includes a main electrode 111 and a connection electrode 112, and in the direction perpendicular to the base substrate, the main electrode 111 overlaps with the light-emitting region 001 of the light-emitting element 100, and the connection electrode 112 does not overlap with the light-emitting region 001 of the light-emitting element 100. For example, the orthographic projection of the light-emitting region 001 of the light-emitting element 100 on the base substrate 01 is completely within the orthographic projection of the main electrode 111 on the base substrate 01. For example, the shape of the main electrode 111 is basically the same as the shape of the light-emitting region 001. For example, the main electrode 111 and the connection electrode 112 in the same first electrode 110 are an integrated structure. For example, the first electrode 110 of the light-emitting element 100 of each sub-pixel 10 includes a main electrode 111 and a connection electrode 112.

In some examples, as shown in FIGS. 2 and 8, the pixel circuit 140 is electrically connected to the connection electrode 112. For example, the first electrode 110 can be connected to one of the source electrode and the drain electrode of a thin film transistor in the pixel circuit 140 through a via penetrating a film layer, such as the first insulating layer 200.

For example, as shown in FIG. 8, the pixel circuit can include a plurality of transistors and at least one capacitor. For example, the pixel circuit can include a light-emitting control transistor; and for example, the light-emitting control transistor includes an active layer 261, a gate electrode 264, a source electrode 262 and a drain electrode 263, and the drain electrode 263 is electrically connected to the first electrode 110 of the light-emitting element 100. For example, the display substrate further includes film layers, such as gate insulating layers 02 and 03, an interlayer insulating layer 04 and a passivation layer 05. For example, the pixel circuit further includes a storage capacitor. For example, between the first insulating layer 200 and the base substrate 01, there are film layers or structures such as the gate insulating layers, the interlayer insulating layer, each film layer in the pixel circuit, a data line, a gate line, a power signal line, a reset power signal line, a reset control signal line, and a light-emitting control signal line, etc.

For example, the pixel circuit can have an 8TIC (that is, eight transistors and one capacitor) structure, or a 7TIC structure, or a 7T2C structure, or a 6TIC structure, or a 6T2C structure or a 9T2C structure, without being limited in the embodiment of the present disclosure.

In some examples, as shown in FIGS. 2 and 8, the first annular defining structure 320 surrounding at least one sub-pixel 10 includes a notch 321, and in the direction perpendicular to the base substrate 01, the notch 321 overlaps with the connection electrode 112. For example, in the direction perpendicular to the base substrate 01, the notch 321 does not overlap with the main electrode 111.

In some examples, as shown in FIG. 1, the base substrate 01 further includes a second region A2, and the first region A1 is located at the periphery of the second region A2. For example, the first region A1 surrounds at least part of the second region A2. For example, the second region A2 shown in FIG. 1 is located in the middle of the top of the base substrate 01. For example, the four sides of the rectangular first region A1 can all surround the second region A2, that is, the second region A2 can be completely surrounded by the first region A1. For example, the second region A2 may not be located in the middle of the top of the base substrate 01 as shown in FIG. 1, but can be located at any other position. For example, the second region A2 can be located at the upper left corner or the upper right corner of the base substrate 01. For example, the first region A1 can include a display region, and the second region A2 can be a display region or a non-display region, such as a hole region (AA hole). For example, the AA hole can be provided with a required hardware structure, such as a photosensitive sensor, etc. For example, the first region A1 can include a display region away from the second region A2 and a non-display region surrounding the second region A2. For example, the first annular defining structure is located in the display region.

For example, the shape of the second region A2 can be a circle or ellipse. But not limited thereto, the shape of the second region A2 can be a polygon, such as a quadrangle, a hexagon or an octagon. For example, the shape of the first region A1 can be a quadrangle, such as a rectangle; but not limited thereto, the shape of the first region A1 can also be a circle, or any polygon other than a quadrangle, such as a hexagon, an octagon, etc.

FIG. 9A is a partial cross-sectional structural view taken along line EE′ as shown in FIG. 1. In some examples, as shown in FIGS. 1, 8 and 9A, the display substrate further includes a second insulating layer 500 located between the defining structure 300 and the base substrate 01.

In some examples, as shown in FIGS. 1, 8 and 9A, the second insulating layer 500 is located at one side of the first insulating layer 200 facing the base substrate 01. For example, in a region other than the region shown in FIG. 9A, the second insulating layer 500 can be stacked with the first insulating layer 200. For example, the region shown in FIG. 9A is not provided with the first insulating layer 200. For example, the region shown in FIG. 9A is a non-display region included in the first region A1.

In some examples, as shown in FIGS. 1, 8 and 9A, the material of the second insulating layer 500 includes an inorganic nonmetallic material, and the material of the second insulating layer 500 is different from the material of the defining structure 300. For example, the material of the defining structure 300 includes silicon nitride, and the material of the second insulating layer 500 includes silicon oxide.

In some examples, as shown in FIGS. 1 and 9A, the second insulating layer 500 includes at least one annular insulating portion 510 surrounding the second region A2, and the defining structure 300 further includes a second annular defining structure 330 in contact with the surface, away from the base substrate 01, of the annular insulating portion 510; and the light-emitting functional layer 130 and the second electrode 120 are both disconnected at the edge of the second annular defining structure 330. FIG. 1 merely illustratively shows the second annular defining structure 330, and does not show the annular insulating portion 510. For example, no sub-pixel for displaying an image is provided between the edges of the second region A2 and the annular insulating portion.

For example, as shown in FIG. 1, the second annular defining structure 330 is located in the first region A1 and surrounds the second region A2. For example, the number of the second annular defining structures 330 can be three, but it is not limited thereto, and the number of the second annular defining structures can be one, two, four or more, which can be set according to product requirements.

The second region is not provided with light-emitting elements, and the light-emitting elements located in the first region can be separated from the second region by setting at least one circle of second annular defining structures around the second region for disconnecting the light-emitting functional layer and the second electrode.

For example, the material of the second annular defining structure 330 includes an inorganic nonmetallic material, such as silicon nitride.

Compared with the design that a general display substrate is provided with an isolation pillar made of a metal material and surrounding the AA hole and the isolation pillar is electrically connected to the second electrode of the light-emitting element, in the display substrate provided by the present disclosure, the second annular defining structure surrounding the second region is made of an inorganic material, and the second annular defining structure has no electrical connection with the second electrode of the light-emitting element, which can avoid the problem of growing dark spot (GDS) in the display region around the AA hole caused by impurities generated during the production process affecting the signal of the second electrode through the second annular defining structure after the second electrode is powered on.

For example, at least some film layers in the light-emitting functional layer 130 can cover the edge of the annular insulating portion 510. For example, at least some film layers in the light-emitting functional layer 130 can cover at least part of the edge of the second annular defining structure 330.

For example, as shown in FIGS. 3, 7A and 9A, the ratio of the thickness of the first annular defining structure 320 to the thickness of the second annular defining structure 330 is in the range of 0.8-1.2. For example, the ratio of the thickness of the first annular defining structure 320 to the thickness of the second annular defining structure 330 is in the range of 0.9-1. For example, the ratio of the thickness of the first annular defining structure 320 to the thickness of the second annular defining structure 330 is in the range of 0.95-1.1. For example, the ratio of the thickness of the first annular defining structure 320 to the thickness of the second annular defining structure 330 is in the range of 0.85-1.

In some examples, as shown in FIGS. 1 and 9A, the orthographic projection of the second annular defining structure 330 on the base substrate 01 is located within the orthographic projection of the annular insulating portion 510 on the base substrate 01.

For example, as shown in FIG. 9A, the orthographic projection of the surface, close to the base substrate, of the second annular defining structure 330 on the base substrate is completely within the orthographic projection of the surface, away from the base substrate, of the second annular defining structure 330 on the base substrate.

In some examples, as shown in FIG. 9A, the cross section of the second annular defining structure 330 includes a second trapezoid 340, and the length of the base 341 of the second trapezoid 340 away from the base substrate is greater than the length of the base 342 of the second trapezoid 340 close to the base substrate.

In some examples, as shown in FIGS. 3, 7A and 9A, the ratio of the size of the first trapezoid 310 in the direction perpendicular to the base substrate 01 to the size of the second trapezoid 340 in the direction perpendicular to the base substrate 01 is in the range of 0.8-1.2, and the ratio of the included angle between a leg of the first trapezoid 310 and the second base 312 to the included angle between a leg of the second trapezoid 340 and a base of the second trapezoid 340 close to the base substrate 01 is in the range of 0.8-1.2.

For example, as shown in FIGS. 3, 7A and 9A, the ratio of the included angle between the leg of the second trapezoid 340 and the base 342 of the second trapezoid 340 to the included angle between the leg of the first trapezoid 310 and the second base 312 of the first trapezoid 310 can be in the range of 0.9-1. For example, the ratio of the included angle between the leg of the second trapezoid 340 and the base 342 of the second trapezoid 340 to the included angle between the leg of the first trapezoid 310 and the second base 312 of the first trapezoid 310 can be in the range of 0.95-1.1.

For example, as shown in FIG. 9A, the included angle between the leg of the second trapezoid 340 and the base 342 of the second trapezoid 340 is in the range of 110-150 degrees. For example, the included angle between the leg of the second trapezoid 340 and the base 342 of the second trapezoid 340 is in the range of 115-130 degrees. For example, the included angle between the leg of the second trapezoid 340 and the base 342 of the second trapezoid 340 is in the range of 112-140 degrees. For example, the included angle between the leg of the second trapezoid 340 and the base 342 of the second trapezoid 340 is in the range of 120-148 degrees. For example, the included angle between the leg of the second trapezoid 340 and the base 342 of the second trapezoid 340 is in the range of 118-135 degrees. For example, the included angle between the leg of the second trapezoid 340 and the base 342 of the second trapezoid 340 is in the range of 122-145 degrees. For example, the included angle between the leg of the second trapezoid 340 and the base 342 of the second trapezoid 340 is in the range of 135-146 degrees.

The second trapezoid in the embodiment of the present disclosure includes a standard trapezoid or an approximate trapezoid; the legs and the two bases in the standard trapezoid are straight edges; and at least one of the legs and the two bases in the general trapezoid is a curved edge. For example, in the case where a leg of the second trapezoid is a curved edge, the curved edge bend towards the midpoint of a base or can bend away from the midpoint of a base.

For example, as shown in FIGS. 4A and 9A, the thickness of the annular insulating portion 510 is greater than the thickness of the protrusion 210. For example, the thickness of the annular insulating portion 510 is greater than the thickness of the second annular defining structure 320.

For example, as shown in FIGS. 2, 3 and 9A, the altitude difference between the second electrode 120 on the first annular defining structure 320 and the second electrode 120 at the outer side of the first annular defining structure 320 is less than the altitude difference between the second electrode 120 on the second annular defining structure 330 and the second electrode 120 at the outer side of the second annular defining structure 330, it can be realized that the second electrode is continuously arranged at the edge of the first annular defining structure, while the second electrode is disconnected at the edge of the second annular defining structure.

For example, FIG. 9A illustratively shows that no second insulating layer 500 is disposed between adjacent annular insulating portions 510, but it is not limited thereto, and a second insulating layer with a relatively small thickness can be disposed between the plurality of annular insulating portions 510, and the plurality of annular insulating portions 510 can be an integrated structure. For example, in the region as shown in FIG. 9A, the thickness of the second insulating layer 500 overlapping with the second annular defining structure 320 is greater than the thickness of the second insulating layer 500 not overlapping with the second annular defining structure 320, so that an annular insulating portion 510 is formed at the overlapping position with the second annular defining structure 320.

In the display substrate provided by the embodiment of the present disclosure, the parameters, such as the thicknesses of the defining structure at respective positions, can be set the same, and at the same time, the thickness of the annular insulating portion can be adjusted, so that the second electrode at the edge of the first annular defining structure can be continuously arranged, and the second electrode at the edge of the second annular defining structure can be disconnected.

In the display substrate provided by the present disclosure, the defining structure between adjacent sub-pixels and the defining structure surrounding the second region are respectively arranged in the first insulating layer and the second insulating layer with different materials, and therefore, it can be realized by a same process that the second electrode is disconnected at the edge of the defining structure surrounding the second region while the second electrode is not disconnected at the edge of the defining structure between adjacent sub-pixels.

For example, as shown in FIGS. 1 and 9A, along the direction pointing from the center of the second region A2 to the edge of the second region A2, the maximum size of the annular insulating portion 510 is greater than the maximum size of the second annular defining structure 330.

For example, as shown in FIG. 9A, the orthographic projection of the second annular defining structure 330 on the base substrate is completely within the orthographic projection of the annular insulating portion 510 on the base substrate.

For example, as shown in FIG. 9A, the cross-section of the annular insulating portion 510 can be a rectangle, and the length of the edge of the rectangle parallel to the base substrate is greater than the length of the base of the second trapezoid 340 away from the base substrate. For example, the distance between adjacent annular insulating portions 510 is less than the distance between adjacent second annular defining structures 330. Of course, the embodiment of the present disclosure is not limited thereto, and the cross-section of the annular insulating portion 510 can be a trapezoid; and for example, the trapezoid can be a regular trapezoid or an inverted trapezoid.

As shown in FIGS. 1-8, an embodiment of the present disclosure provides a display substrate, which includes a base substrate 01 and a plurality of sub-pixels 10 located on the base substrate 01. The base substrate 01 at least includes a first region A1; the plurality of sub-pixels 10 are located in the first region A1 of the base substrate 01, each sub-pixel 10 in at least some sub-pixels 10 includes a light-emitting element 100, the light-emitting element 100 includes a light-emitting functional layer 130 and a first electrode 110 and a second electrode 120 located at both sides of the light-emitting functional layer 130 along the direction perpendicular to the base substrate 01, the first electrode 110 is located between the light-emitting functional layer 130 and the base substrate 01, and the light-emitting functional layer 130 includes a plurality of film layers. The display substrate further includes a defining structure 300, at least one defining structure 300 is disposed between at least two adjacent sub-pixels 10, and the plurality of sub-pixels 10 include a first sub-pixel, a second sub-pixel and a third sub-pixel. For example, the first sub-pixel, the second sub-pixel and the third sub-pixel can be sub-pixels emitting light of three different colors, such as a first color sub-pixel 101, a second color sub-pixel 102 and a third color sub-pixel 103, respectively. Taking that the first sub-pixel is the first color sub-pixel 101, the second sub-pixel is the second color sub-pixel 102 and the third sub-pixel is the third color sub-pixel 103 as an example, the second sub-pixel 102 and the third sub-pixel 103 are both adjacent to the first sub-pixel 101.

As shown in FIG. 6, the second sub-pixel 102 and the third sub-pixel 103 are both adjacent to the first sub-pixel 101, the maximum size of the defining structure 300 disposed between the first sub-pixel 101 and the second sub-pixel 102 along the arrangement direction of these two sub-pixels is a first size D1, the maximum size of the defining structure 300 disposed between the first sub-pixel 101 and the third sub-pixel 103 along the arrangement direction of these two sub-pixels is a second size D2, and the first size D1 is different from the second size D2. For example, the arrangement direction of the first sub-pixel 101 and the second sub-pixel 102 can be the U direction or the V direction, and the arrangement direction of the first sub-pixel 101 and the third sub-pixel 103 can be the X direction or the Z direction. “The second sub-pixel 102 and the third sub-pixel 103 being both adjacent to the first sub-pixel 101” can mean that along the arrangement direction of the first sub-pixel and the second sub-pixel, no other sub-pixel is arranged between these two sub-pixels; and along the arrangement direction of the first sub-pixel and the third sub-pixel, and no other sub-pixel is arranged between these two sub-pixels.

By setting the sizes of the defining structures between different adjacent sub-pixels, the matching of the arrangement relationship of the sub-pixels and the defining structure can be improved, and the conduction effect of the second electrode can be improved.

For example, as shown in FIG. 6, the first size D1 is greater than the second size D2. Of course, in the case where different color sub-pixels are selected as the first sub-pixel, the second sub-pixel and the third sub-pixel, the relationship between the first size and the second size may change accordingly.

In some examples, as shown in FIG. 6, the plurality of sub-pixels 10 are arrayed along a first direction and a second direction, some pixels 10 in the plurality of sub-pixels 10 are arrayed along a third direction and a fourth direction, the first direction is perpendicular to the second direction, the third direction is perpendicular to the fourth direction, and the first direction is intersected with the third direction. For example, the embodiment of the present disclosure illustratively shows that one of the first direction and the second direction is the U direction and the other of the first direction and the second direction is the V direction; one of the third direction and the fourth direction is the X direction and the other of the third direction and the fourth direction is the Z direction. For example, the plurality of second color sub-pixels 102 are arrayed along the third direction and the fourth direction. For example, the first color sub-pixels 101 and the third color sub-pixels 103 are alternately arranged along the third direction and also alternately arranged along the fourth direction, so that the plurality of first color sub-pixels and the plurality of third color sub-pixels are arrayed along the third direction and the fourth direction.

In some examples, as shown in FIG. 6, the maximum size of the defining structure 300 between two adjacent sub-pixels 10 arranged along the first or second direction along the arrangement direction of these two sub-pixels 10 is a third size D3, the maximum size of the defining structure 300 between two adjacent sub-pixels 10 arranged along the third or fourth direction along the arrangement direction of these two sub-pixels 10 is a fourth size D4, and the third size D3 is less than the fourth size D4.

For example, as shown in FIG. 6, the third size D3 can be the size of the defining structure 300 disposed between two parallel edges of two adjacent sub-pixels 10 in the direction perpendicular to the two parallel edges, and the fourth size D4 can be the size of the defining structure 300 disposed between two opposite corners of two adjacent sub-pixels in the direction parallel to the connecting line of the two corners.

In some examples, as shown in FIG. 6, the plurality of sub-pixels 10 include a plurality of green sub-pixels 102, a plurality of blue sub-pixels 103 and a plurality of red sub-pixels 101, and the maximum size of the defining structure 300 disposed between two adjacent green sub-pixels 102 along the arrangement direction of these two green sub-pixels 102 is greater than the maximum size of the defining structure 300 disposed between other adjacent sub-pixels 10 along the arrangement direction of the other adjacent sub-pixels 10.

For example, the maximum size of the defining structure 300 disposed between two adjacent green sub-pixels 102 along the arrangement direction of these two green sub-pixels 102 can be D5, and the maximum size of the defining structure 300 disposed between other adjacent sub-pixels 10 along the arrangement direction of the other adjacent sub-pixels 10 can be D3 or D4. For example, the other adjacent sub-pixels 10 can refer to a red sub-pixel and a green sub-pixel adjacent to each other, a blue sub-pixel and a red sub-pixel adjacent to each other, or a blue sub-pixel and a green sub-pixel adjacent to each other.

In some examples, as shown in FIGS. 2, 6 and 8, each sub-pixel 10 in at least some sub-pixels 10 further includes a pixel circuit 140, the first electrode 110 of the light-emitting element 100 of at least one sub-pixel 10 includes a main electrode 111 and a connection electrode 112; and in the direction perpendicular to the base substrate, the main electrode 111 overlaps with the light-emitting region of the light-emitting element 100, the connection electrode 112 does not overlap with the light-emitting region of the light-emitting element 100, and the pixel circuit 140 is electrically connected with the connection electrode 112. In at least a partial region of the first region A1, at least one film layer in the light-emitting functional layer 130 is disconnected at the edge of the defining structure 300, and at least part of the second electrode 120 is continuously arranged at the overlapping position with the connection electrode 112.

For example, as shown in FIGS. 6 and 8, the first electrode 110 is electrically connected to the pixel circuit 140 through an anode via 201 penetrating the first insulating layer 200, and the second electrode 120 is continuously arranged at the position of the anode via 201.

In some examples, as shown in FIGS. 2, 6 and 8, in the direction perpendicular to the base substrate, the defining structure 300 does not overlap with at least part of the connection electrode 112. For example, in the direction perpendicular to the base substrate, the defining structure 300 does not overlap with the anode via 201.

In some examples, as shown in FIGS. 2 and 6, the second electrodes 120 in at least some sub-pixels 10 include a planar structure or a mesh structure.

FIG. 7B is a planar view of a second electrode covering a defining structure provided by an embodiment of the present disclosure. For example, the second electrode 120 is a transparent electrode, which is shown as a translucent filling pattern in FIG. 7B. For example, as shown in FIG. 7B, the second electrode 120 can be a planar structure covering the plurality of sub-pixels 10, that is, the plurality of sub-pixels 10 share the second electrode 120 having the planar structure; and the second electrode 120 is continuous at respective positions, especially at the edge of the defining structure 300, and for example, the full-screen cathode is all continuous. Of course, the embodiment of the present disclosure is not limited thereto, because of the problems of process stability and uniformity, if the second electrode cannot always be continuous in some regions, it is necessary to reserve an overlapping channel RO that can ensure the second electrode in these regions to form a mesh structure. For example, the second electrode is continuous at the position of the anode via, so as to form the overlapping channel RO. For example, the overlapping channel RO includes a portion extending along the U direction and a portion extending along the V direction, and in this case, the second electrode can be formed as a mesh structure.

For example, the position where a spacer (PS) is disposed on the display panel can also be the position where the overlapping channel RO of the second electrode passes through. For example, in the direction perpendicular to the base substrate, the defining structure does not overlap with the spacer.

For example, the mesh overlapping mode of the second electrode can be flexibly designed according to the shape of the sub-pixel, and for example, at least one notch is reserved around the sub-pixel as a path for the mesh overlapping of the second electrode.

For example, as shown in FIG. 6, the size D3 of the defining structure 300 can be in the range of 2.2-2.7 microns, such as 2.5 microns.

For example, as shown in FIG. 6, the ratio of the distances between the defining structure 300 and the openings, which define the light-emitting regions of different color sub-pixels 10, of the pixel defining pattern is in the range of 0.9-1.1, such as 1. For example, the distance between the defining structure 300 and the opening, which defines the light-emitting region of the green sub-pixel 102, of the pixel defining pattern can be in the range of 8-10 microns, such as 8.5 microns. For example, the distance between the defining structure 300 and the opening, which defines the light-emitting region of the blue sub-pixel 103, of the pixel defining pattern can be in the range of 8-10 microns, such as 8.5 microns. For example, the distance between the defining structure 300 and the opening, which defines the light-emitting region of the red sub-pixel 101, of the pixel defining pattern can be in the range of 8-10 microns, such as 8.5 microns.

For example, as shown in FIG. 6, the size D4 of the defining structure 300 can be in the range of 10⁻¹⁴ microns, such as 12.5 microns. For example, the size D5 of the defining structure 300 can be in the range of 18-20 microns, such as 19.5 microns.

For example, as shown in FIG. 6, the distance between the light-emitting regions of two adjacent sub-pixels 10 arranged along the U direction or the V direction can be in the range of 18-22 microns, such as 20 microns. For example, the distance between two adjacent openings of the pixel defining pattern arranged along the U direction or the V direction can be 20 microns.

FIG. 9B is a partial cross-sectional structural view of a first region being close to a second region provided by an example of the embodiment of the present disclosure. As shown in FIG. 9B, layers disposed on the base substrate include a buffer layer and a shielding layer 021, an active layer 026 on the buffer layer and the shielding layer 021, a gate insulating layer 022 on the active layer 026, a metal layer 028 on the gate insulating layer 022, a gate insulating layer 023 on the metal layer 028, a metal layer 027 on the gate insulating layer 023, an interlayer insulating layer 024 on the metal layer 027, a metal layer 031 on the interlayer insulating layer 024, a planarization layer 025 on the metal layer 031, and a planarization layer 200 on the planarization layer 025. The region A11 is a region where the sub-pixels 100 are arranged, and the region A12 is a region surrounding the second region and provided with the second annular defining structure 330.

For example, as shown in FIGS. 8-9B, the annular insulating portion 510 and the second insulating layer 500 can include the gate insulating layer 022, the gate insulating layer 023, and the interlayer insulating layer 024.

For example, as shown in FIG. 9B, while the interlayer insulating layer 024, the gate insulating layer 022 and the gate insulating layer 023 in the region A12 are etched to form a via hole 041, the interlayer insulating layer 024, the gate insulating layer 022, and the gate insulating layer 023 in the region A11 are etched to form a gap 042; and then the metal layer 031, the planarization layer 025, and the planarization layer 200 formed in the region A12 are removed by patterning, so as to form the defining structures 300 in the region A11 and the region A12 at the same time. Therefore, the defining structure surrounding the second region is formed while the defining structure between adjacent pixels is formed; and the masks for forming the defining structures at two positions are merged and compatible, which is helpful to reduce the number of masks and further reduce the cost of producing the display substrate.

FIG. 10 is a schematic block diagram of a display device provided by another embodiment of the present disclosure. As shown in FIG. 10, the display device provided by the embodiment of the present disclosure includes any above display substrate as mentioned above.

In the display device provided by the present disclosure, the first annular defining structure realizes the continuous arrangement of the second electrode while isolating at least one film layer in the light-emitting functional layer, which can reduce the crosstalk between adjacent sub-pixels and avoid the problem of brightness uniformity caused by a large-area fracture of the second electrode.

In the display device provided by the present disclosure, the light-emitting elements located in the first region can be separated from the second region by setting at least one circle of second annular defining structures around the second region for disconnecting the light-emitting functional layer and the second electrode.

For example, the display device further includes a cover plate located at the light-exiting side of the display substrate.

For example, the display device can be a display, such as an organic light-emitting diode display, etc., or any product or component having display function and including the display, such as a TV, a digital camera, a mobile phone, a watch, a tablet computer, a notebook computer, a navigator, etc., without being limited in the present embodiment.

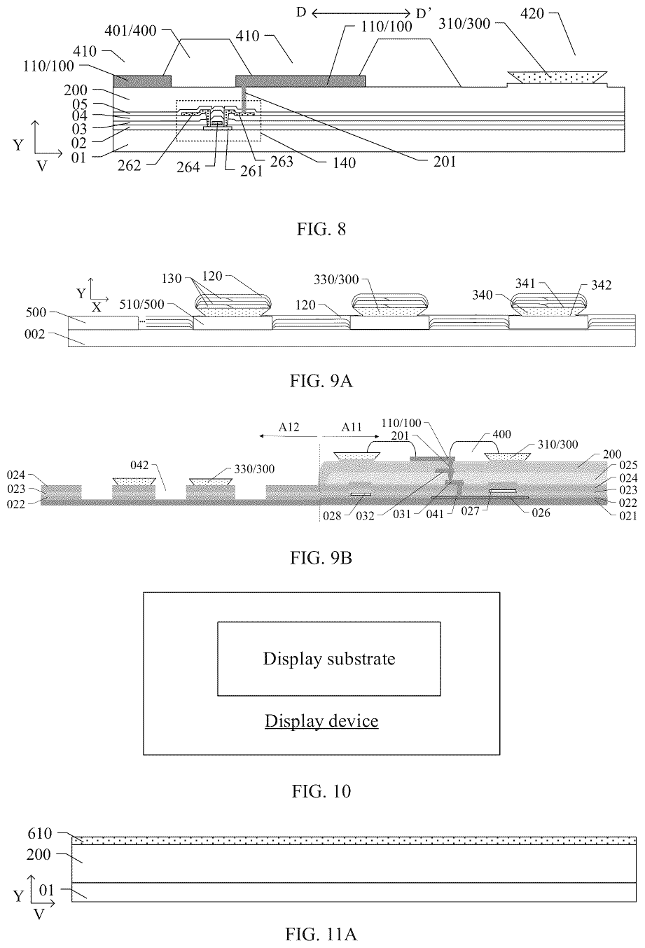

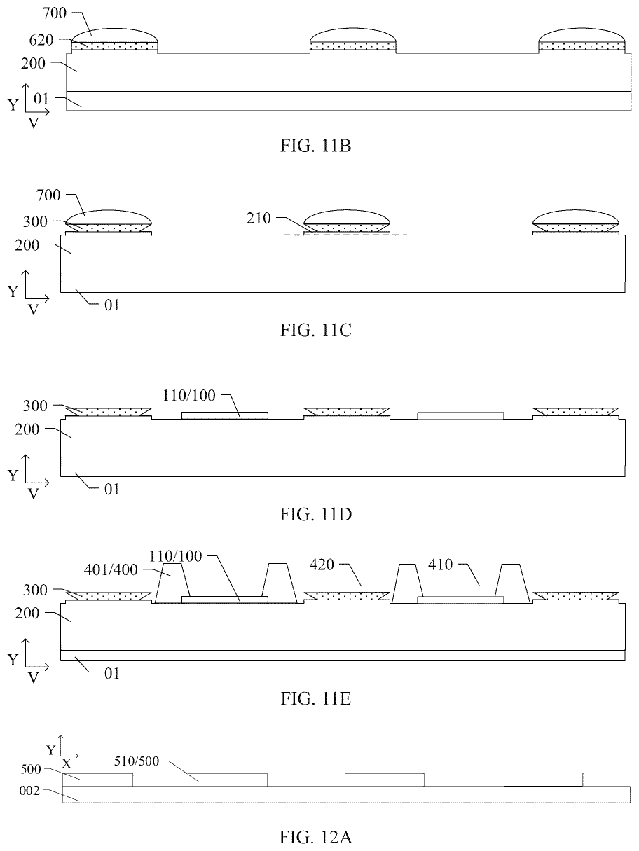

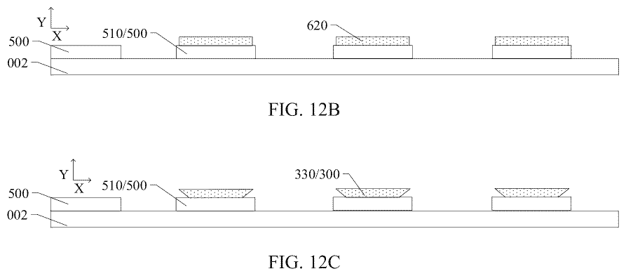

FIGS. 11A-11E are schematic process flow charts of a manufacturing method of a partial region of a display substrate provided by an embodiment of the present disclosure. The display substrate shown in FIG. 3 in the region A11 shown in FIG. 1 can be formed by the manufacturing method shown in FIGS. 11A-11E. FIGS. 12A-12C are schematic process flow charts of a manufacturing method of another partial region of a display substrate provided by an embodiment of the present disclosure. The display substrate shown in FIG. 9A can be formed by the manufacturing method shown in FIGS. 12A-12C.

As shown in FIG. 11A, the manufacturing method of the display substrate includes: providing a base substrate 01; and forming an inorganic nonmetallic material layer 610 on the base substrate 01.

In some examples, as shown in FIG. 11A, before forming the inorganic nonmetallic material layer 610, the manufacturing method further includes forming a first insulating layer 200 on the base substrate 01. In a partial region of the first region, the inorganic nonmetallic material layer 610 is formed on the surface of the first insulating layer 200.

In some examples, as shown in FIGS. 12A, 8 and 9A, before forming the first insulating layer 200, the manufacturing method further includes forming a second insulating layer 500 (the interlayer insulating layer 04 as shown in FIG. 8) on the base substrate 01. In another partial region of the first region, the inorganic nonmetallic material layer 610 is formed on the surface of the second insulating layer 200.

For example, as shown in FIGS. 11A and 12A, the inorganic nonmetallic material layer 610 is deposited on the surfaces of the first insulating layer 200 and the second insulating layer 500. For example, the inorganic nonmetallic material layer 610 has the thickness in the range of 300-550 angstroms. For example, the thickness of the inorganic nonmetallic material layer 610 can be 500 angstroms. For example, the material of the inorganic nonmetallic material layer 610 may be silicon nitride (SiNx).

In some examples, as shown in FIGS. 11A and 11B, a shielding structure 700 is formed at one side of the inorganic nonmetallic material layer 610 away from the base substrate 01. For example, a mask layer is coated on the inorganic nonmetallic material layer 610. For example, the material of the mask layer includes photoresist. For example, the mask layer is patterned to form the shielding structure 700.

In some examples, as shown in FIGS. 11A and 11B, by taking the shielding structure 700 as a mask and using a first gas, the inorganic nonmetallic material layer 610 is etched to form a defining pattern 620.

For example, the first gas includes a mixed gas of carbon tetrafluoride (CF4) and oxygen. For example, in the process of etching the inorganic nonmetallic material layer 610 with the first gas to form the defining pattern 620, the first gas will etch the first insulating layer 200 at the outer side of the defining pattern 620 to a certain extent, so as to form a recess, such as loss. Therefore, the first insulating layer 200 directly below the defining pattern 620 has a protrusion, and the thickness of the first insulating layer 200 at this position is greater than the thickness of the first insulating layer 200 at other position (where the recess is located).

For example, in a post-treatment process, the difference between the thickness of the first insulating layer 200 directly below the defining pattern 620 and the thickness of the first insulating layer 200 at other position can be minimized by adjusting the first gas. For example, there may be no need to perform the post-treatment process to further reduce the difference between the thickness of the first insulating layer directly below the defining pattern and the thickness of the first insulating layer at other position.

In some examples, as shown in FIGS. 11A-11C, by taking the shielding structure 700 as a mask and using a second gas, the defining pattern 620 is etched to form a defining structure 300.

For example, after the defining pattern 620 is formed, the shielding structure 700 is retained on the defining pattern 620 and is not removed.

For example, the second gas includes a mixed gas of sulfur hexafluoride (SF6) and oxygen. For example, SF6 can chemically react with silicon nitride to etch the sidewall of silicon nitride, so that the cross-section of the defining structure 300 forms an inverted trapezoidal shape. For example, the second gas will not etch the second insulating layer 200, and the protrusions 210 of the second insulating layer 200 formed in the previous etching process will not be further etched.

As shown in FIGS. 1-3 and 11A-11E, the manufacturing method of the display substrate includes forming a plurality of sub-pixels 10 in at least a first region A1 of the base substrate 01. At least one defining structure 300 is disposed between at least two adjacent sub-pixels 10, each sub-pixel 10 in at least some sub-pixels 10 includes a light-emitting element 100. Forming the light-emitting element 100 includes sequentially forming a first electrode 110, a light-emitting functional layer 130 and a second electrode 120 which are stacked in a direction perpendicular to the base substrate 01. The first electrode 110 is located between the second electrode 120 and the base substrate 01, and the light-emitting functional layer 130 includes a plurality of film layers.

For example, before forming the first insulating layer 200, the manufacturing method further includes forming, on the base substrate 01, other film layers, such as a gate insulating layer, a buffer layer, a passivation layer, multi-layer conductive layers, etc.

In some examples, as shown in FIGS. 3 and 11C, a first orthographic projection 301 of the surface, close to the base substrate 01, of the defining structure 300 between adjacent sub-pixels 10 on the base substrate 01 is completely located within a second orthographic projection 302 of the surface, away from the base substrate 01, of the defining structure 300 on the base substrate 01; and along an arrangement direction of light-emitting regions of the adjacent sub-pixels 10, the maximum size S2 of the second orthographic projection 302 is greater than the maximum size S1 of the first orthographic projection 301.

In some examples, as shown in FIG. 3, in at least a partial region of the first region, at least one film layer in the light-emitting functional layer 130 is disconnected at the edge of the defining structure 300, and the second electrodes 120 are continuously arranged at the edge of the defining structure 300.

In the embodiment of the present disclosure, the shielding structure is taken as a mask, and two different gases are used to perform two-step etching on the nonmetallic material layer, so as to form a defining structure having a structure similar to undercut, thus realizing the continuous arrangement of the second electrode while isolating at least one film layer in the light-emitting functional layer. And therefore, the crosstalk between adjacent sub-pixels can be reduced, and at the same time, the problem of brightness uniformity caused by a large-area fracture of the second electrode can be avoided.

In some examples, as shown in FIGS. 11B and 11C, the cross-sectional shape of the defining pattern 620, cut by a plane where the center connecting lines of adjacent sub-pixels respectively located at both sides of the defining pattern 620 is located, includes a rectangle; and the cross-sectional shape of the defining structure 300 cut by the plane includes a first trapezoid, a length of a base of the first trapezoid away from the base substrate 01 is greater than a length of a base of the first trapezoid close to the base substrate 01, and the plane is perpendicular to the base substrate 01.

For example, the first orthographic projection of the defining structure 300 is completely within the orthographic projection of the protrusion 210 on the base substrate 01.

For example, as shown in FIG. 11C, the distance between the orthographic projections of the edges of the protrusion 210 and the shielding structure 700 on the base substrate is less than 0.5 micron. For example, the distance between the orthographic projections of the edges of the protrusion 210 and the shielding structure 700 on the base substrate is less than 0.4 micron. For example, the distance between the orthographic projections of the edges of the protrusion 210 and the shielding structure 700 on the base substrate is less than 0.3 micron. For example, the distance between the orthographic projections of the edges of the protrusion 210 and the shielding structure 700 on the base substrate is less than 0.2 micron. For example, the distance between the orthographic projections of the edges of the protrusion 210 and the shielding structure 700 on the base substrate is less than 0.1 micron.

For example, as shown in FIG. 11C, the edge of the protrusion 210 is flush with the edge of the shielding structure 700.

For example, as shown in FIG. 11C, the distance between the orthographic projections of the edge of the protrusion 210 and the edge of the surface, away from the base substrate 01, of the defining structure 300 on the base substrate 01 is less than 0.5 micron. For example, the distance between the orthographic projections of the edge of the protrusion 210 and the edge of the surface, away from the base substrate 01, of the defining structure 300 on the base substrate 01 is less than 0.4 micron. For example, the distance between the orthographic projections of the edge of the protrusion 210 and the edge of the surface, away from the base substrate 01, of the defining structure 300 on the base substrate 01 is less than 0.3 micron. For example, the distance between the orthographic projections of the edge of the protrusion 210 and the edge of the surface, away from the base substrate 01, of the defining structure 300 on the base substrate 01 is less than 0.2 micron. For example, the distance between the orthographic projections of the edge of the protrusion 210 and the edge of the surface, away from the base substrate 01, of the defining structure 300 on the base substrate 01 is less than 0.1 micron.

For example, as shown in FIG. 11C, the edge of the protrusion 210 is flush with the edge of the surface, away from the base substrate 01, of the defining structure 300. For example, a straight line extending along the direction perpendicular to the base substrate 01 passes through the edge of the protrusion 210 and the edge of the surface, away from the base substrate 01, of the defining structure 300. For example, the second orthographic projection completely coincides with the orthographic projection of the protrusion 210 on the base substrate 01.

In some examples, as shown in FIG. 11D, after forming the defining structure 300, the manufacturing method further includes removing the shielding structure 300.

In some examples, as shown in FIG. 11D, the first electrode 110 is formed by patterning after the defining structure 300 is formed.

For example, as shown in FIG. 11C, after removing the shielding structure 300, a conductive layer is formed on the first insulating layer 200, and the conductive layer is patterned to form the first electrode 110. For example, the first electrode 110 is patterned by a wet etching process, and the conductive layer at the inclined sidewall of the defining structure can be completely removed during the wet etching process.

For example, as shown in FIG. 11E, after the first electrode 110 is formed, an organic material layer is formed on the first electrode 110, and the organic material layer is patterned to form a pixel defining pattern 400. For example, the pixel defining pattern 400 includes a plurality of first openings 410, one sub-pixel 10 corresponds to at least one first opening 410, and the first opening 410 is configured to expose the first electrode 110.

For example, as shown in FIG. 11E, the pixel defining pattern 400 further includes a second opening 420, and at least part of the defining structure 300 is exposed by the second opening 420. FIG. 11E illustratively shows that the defining structure 300 is completely exposed by the second opening 420, but not limited to thereto, and the defining structure 300 can be merely partially exposed by the second opening 420 as shown in FIG. 5. For example, at least one film layer in the light-emitting functional layer 130 is disconnected at at least part of an edge of the defining structure 300 exposed by the second opening 420, and the second electrode 120 is continuously arranged at this edge.

In some examples, as shown in FIGS. 11A-12C, etching, by using the first gas, the inorganic nonmetallic material layer 610 to form the defining pattern 620 includes simultaneously etching the inorganic nonmetallic material layer 610 on the first insulating layer 200 and the inorganic nonmetallic material layer 610 on the second insulating layer 500 to form the defining pattern 620; and etching, by using the second gas, the defining pattern 620 to form the defining structure 300 includes simultaneously etching the defining pattern 620 on the first insulating layer 200 and the defining pattern 620 on the second insulating layer 500 to form the defining structure 300.

For example, as shown in FIG. 12A, after an inorganic layer is formed, the inorganic layer is patterned to form a second insulating layer 500, and the second insulating layer 500 includes a continuous film layer away from the second region A2 shown in FIG. 1 and an annular insulating portion 510 close to the second region A2 shown in FIG. 1. For example, the annular insulating portion 510 can be integrally arranged with the continuous film layer, or the annular insulating portion 510 can be spaced apart from the continuous film layer.

For example, as shown in FIG. 12B, after the annular insulating portion 510 is formed, the film layers, such as the first insulating layer, formed thereon are etched away, so that the subsequent inorganic nonmetallic material layer 610 is formed on the surface of the annular insulating portion 510. For example, a defining pattern 620 is patterned on the annular insulating portion 510.

For example, the defining pattern 620 shown in FIG. 12B can be formed at the same time as the defining pattern 620 shown in FIG. 11B. The method of forming the defining pattern 620 shown in FIG. 12B is the same as the method of forming the defining pattern 620 shown in FIG. 11B, which will not be repeated here.

FIGS. 12B-12C omit the shielding structure 700 shown in FIGS. 11B-11C.

For example, as shown in FIG. 12C, after the defining pattern 620 is formed, the defining pattern 620 is etched by using a second gas to form a second annular defining structure 330. For example, SF6 can chemically react with silicon nitride to etch the sidewall of silicon nitride, so that the cross-section of the second annular defining structure 330 forms an inverted trapezoidal shape.

For example, the second annular defining structure 330 shown in FIG. 12C can be formed at the same time as the defining structure 300 shown in FIG. 11C, such as the first annular defining structure.

In the manufacturing method of the display substrate provided by the present disclosure, the defining structure surrounding the second region is formed while the defining structure between adjacent pixels is formed; and the masks for forming the defining structures at two positions are merged and compatible, which is helpful to reduce the number of masks and further reduce the cost of producing the display substrate.

In the manufacturing method of the display substrate provided by the present disclosure, the defining structure between adjacent sub-pixels and the defining structure surrounding the second region are respectively formed in the first insulating layer and the second insulating layer with different materials, which is helpful to realizing the compatibility of manufacturing methods of defining structures at different positions and having different functions, so as to reduce the number of masks.

The following statements should be noted:
(1) In the accompanying drawings of the embodiments of the present disclosure, the drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto, and the protection scope of the present disclosure should be based on the protection scope of the claims.

1. A display substrate, comprising:
a base substrate, at least comprising a first region;
a plurality of sub-pixels located in the first region of the base substrate, wherein each sub-pixel in at least part of the plurality of sub-pixels comprises a light-emitting element, the light-emitting element comprises a light-emitting functional layer, and a first electrode and a second electrode located at both sides of the light-emitting functional layer along a direction perpendicular to the base substrate, the first electrode is located between the light-emitting functional layer and the base substrate, and the light-emitting functional layer comprises a plurality of film layers,
wherein the display substrate further comprises a defining structure, and at least one defining structure is disposed between at least two adjacent sub-pixels; a first orthographic projection of a surface, close to the base substrate, of the defining structure between adjacent sub-pixels on the base substrate is completely located within a second orthographic projection of a surface, away from the base substrate, of the defining structure on the base substrate; in an arrangement direction of light-emitting regions of the adjacent sub-pixels, a maximum size of the second orthographic projection is greater than a maximum size of the first orthographic projection, and the defining structure comprises an inorganic nonmetallic material;
in at least a partial region of the first region, at least one film layer in the light-emitting functional layer is disconnected at an edge of the defining structure, and second electrodes of adjacent sub-pixels are at least partially continuously arranged.

2. The display substrate according to claim 1, wherein the second electrodes are continuously arranged at the edge of the defining structure.

3. The display substrate according to claim 1,
wherein the second electrode of at least one sub-pixel and the second electrode of one sub-pixel adjacent thereto in a first sub-direction are continuously arranged, the second electrode of the at least one sub-pixel and the second electrode of one sub-pixel adjacent thereto in a second sub-direction are disconnected, and the first sub-direction is intersected with the second sub-direction; and/or,
the second electrode of at least one sub-pixel and the second electrode of one sub-pixel adjacent thereto in a first sub-direction are continuously arranged, the second electrode of the at least one sub-pixel and the second electrode of one sub-pixel adjacent thereto in a second sub-direction are continuously arranged, and the first sub-direction is intersected with the second sub-direction.

4. (canceled)

5. The display substrate according to claim 1, wherein the second electrode of at least one sub-pixel and the second electrode of one sub-pixel adjacent thereto are continuously arranged, and a minimum width of the second electrode between these two adjacent sub-pixels is greater than 1 micron in a direction perpendicular to an arrangement direction of these two adjacent sub-pixels.

6. The display substrate according to claim 5, wherein an orthographic projection of a center connecting line of these two adjacent sub-pixels on a plane where the second electrode is located is within the second electrode.

7. (canceled)

8. The display substrate according to claim 1, wherein a cross-sectional shape of the defining structure cut by a plane where a center connecting line of the adjacent sub-pixels is located comprises a first trapezoid, a length of a first base of the first trapezoid away from the base substrate is greater than a length of a second base of the first trapezoid close to the base substrate, and the plane is perpendicular to the base substrate.

9. The display substrate according to claim 8, wherein an included angle between at least part of at least one leg of the first trapezoid and the second base is in a range of 110-150 degrees, and/or,
a thickness of the defining structure is in a range of 300-550 angstroms.

10. (canceled)

11. The display substrate according to claim 1, further comprising:
a first insulating layer, located between the defining structure and the base substrate,
wherein, in at least the partial region of the first region, the first insulating layer is in contact with the surface of the defining structure facing the base substrate, the first insulating layer is located between the first electrode and the base substrate, and a material of the first insulating layer comprises an organic material.

12. The display substrate according to claim 11, wherein the first insulating layer comprises a protrusion in contact with the surface of the defining structure, and the first orthographic projection is completely located within an orthographic projection of the protrusion on the base substrate.

13. The display substrate according to claim 12, wherein a distance between orthographic projections of an edge of the protrusion and an edge of the surface, away from the base substrate, of the defining structure on the base substrate is less than 0.5 micron.

14. (canceled)

15. The display substrate according to claim 1, further comprising:
a pixel defining pattern, located at a side of the first electrode away from the base substrate, wherein at least the pixel defining pattern located in the first region comprises a plurality of first openings, one sub-pixel corresponds to at least one first opening, the light-emitting element of the sub-pixel is at least partially located in the first opening corresponding to the sub-pixel, and the first opening is configured to expose the first electrode,
wherein the pixel defining pattern further comprises a second opening, and at least part of the defining structure is exposed by the second opening.

16-17. (canceled)

18. The display substrate according to claim 1, wherein the plurality of sub-pixels comprises a plurality of first color sub-pixels, a plurality of second color sub-pixels and a plurality of third color sub-pixels, the defining structure comprises a plurality of first annular defining structures, and the plurality of first annular defining structures surrounds at least one sub-pixel among the plurality of first color sub-pixels, the plurality of second color sub-pixels and the plurality of third color sub-pixels;
wherein each sub-pixel in the at least part of the plurality of sub-pixels further comprises a pixel circuit, and the first electrode of the light-emitting element of at least one sub-pixel comprises a main electrode and a connection electrode, and in the direction perpendicular to the base substrate, the main electrode overlaps with the light-emitting region of the light-emitting element, and the connection electrode does not overlap with the light-emitting region of the light-emitting element;
the pixel circuit is electrically connected to the connection electrode, and the first annular defining structure surrounding the at least one sub-pixel comprises a notch, and in the direction perpendicular to the base substrate, the first annular defining structure does not overlap with the connection electrode.

19. (canceled)

20. The display substrate according to claim 11, further comprising:
a second insulating layer, located between the defining structure and the base substrate,
wherein the base substrate further comprises a second region, and the first region is located at a periphery of the second region;
the second insulating layer comprises at least one annular insulating portion surrounding the second region, the defining structure further comprises a second annular defining structure in contact with a surface, away from the base substrate, of the annular insulating portion, the second insulating layer is located at a side of the first insulating layer facing the base substrate, a material of the second insulating layer comprises an inorganic nonmetallic material, the material of the second insulating layer is different from the material of the defining structure, and the light-emitting functional layer and the second electrode are both disconnected at an edge of the second annular defining structure.

21-22. (canceled)

23. The display substrate according to claim 20, wherein a cross-section of the second annular defining structure comprises a second trapezoid, and a length of a base of the second trapezoid away from the base substrate is greater than a length of a base of the second trapezoid close to the base substrate;
a cross-sectional shape of the defining structure cut by a plane where a center connecting line of the adjacent sub-pixels is located comprises a first trapezoid, a length of a first base of the first trapezoid away from the base substrate is greater than a length of a second base of the first trapezoid close to the base substrate, and the plane is perpendicular to the base substrate;
a ratio of a size of the first trapezoid in the direction perpendicular to the base substrate to a size of the second trapezoid in the direction perpendicular to the base substrate is in a range of 0.8-1.2, and a ratio of an included angle between a leg of the first trapezoid and the second base to an included angle between a leg of the second trapezoid and the base of the second trapezoid close to the base substrate is in a range of 0.8-1.2.

24. A display substrate, comprising:
a base substrate, at least comprising a first region;
a plurality of sub-pixels located in the first region of the base substrate, wherein each sub-pixel in at least part of the plurality of sub-pixels comprises a light-emitting element, the light-emitting element comprises a light-emitting functional layer, and a first electrode and a second electrode located at both sides of the light-emitting functional layer in a direction perpendicular to the base substrate, the first electrode is located between the light-emitting functional layer and the base substrate, and the light-emitting functional layer comprises a plurality of film layers,
wherein the display substrate further comprises a defining structure, at least one defining structure is disposed between at least two adjacent sub-pixels, the plurality of sub-pixels comprises a first sub-pixel, a second sub-pixel and a third sub-pixel, the second sub-pixel and the third sub-pixel are both adjacent to the first sub-pixel, a maximum size of the defining structure disposed between the first sub-pixel and the second sub-pixel in an arrangement direction of these two sub-pixels is a first size, a maximum size of the defining structure disposed between the first sub-pixel and the third sub-pixel in an arrangement direction of these two sub-pixels is a second size, and the first size is different from the second size.

25. The display substrate according to claim 24, wherein the plurality of sub-pixels is arrayed along a first direction and a second direction, some pixels in the plurality of sub-pixels are arrayed along a third direction and a fourth direction, the first direction is perpendicular to the second direction, the third direction is perpendicular to the fourth direction, and the first direction is intersected with the third direction;
a maximum size of the defining structure between two adjacent sub-pixels arranged along the first direction or the second direction in an arrangement direction of these two sub-pixels is a third size, a maximum size of the defining structure between two adjacent sub-pixels arranged along the third direction or the fourth direction in an arrangement direction of these two sub-pixels is a fourth size, and the third size is less than the fourth size.

26. The display substrate according to claim 2, wherein the plurality of sub-pixels comprises a plurality of green sub-pixels, a plurality of blue sub-pixels and a plurality of red sub-pixels, and a maximum size of the defining structure disposed between two adjacent green sub-pixels in an arrangement direction of these two green sub-pixels is greater than a maximum size of the defining structure disposed between other adjacent sub-pixels in an arrangement direction of the other adjacent sub-pixels.

27-29. (canceled)

30. A display device, comprising the display substrate according to claim 1.

31. A manufacturing method of a display substrate, comprising:
providing a base substrate;
forming an inorganic nonmetallic material layer on the base substrate;
forming a shielding structure at a side of the inorganic nonmetallic material layer away from the base substrate;
etching, by taking the shielding structure as a mask and using a first gas, the inorganic nonmetallic material layer to form a defining pattern;
etching, by taking the shielding structure as a mask and using a second gas, the defining pattern to form a defining structure;
forming a plurality of sub-pixels in at least a first region of the base substrate,
wherein at least one defining structure is disposed between at least two adjacent sub-pixels, each sub-pixel in at least part of the plurality of sub-pixels comprises a light-emitting element, forming the light-emitting element comprises sequentially forming a first electrode, a light-emitting functional layer and a second electrode which are stacked in a direction perpendicular to the base substrate, the first electrode is located between the second electrode and the base substrate, and the light-emitting functional layer comprises a plurality of film layers;
a first orthographic projection of a surface, close to the base substrate, of the defining structure between adjacent sub-pixels on the base substrate is completely located within a second orthographic projection of a surface, away from the base substrate, of the defining structure on the base substrate; in an arrangement direction of light-emitting regions of the adjacent sub-pixels, a maximum size of the second orthographic projection is greater than a maximum size of the first orthographic projection;
in at least a partial region of the first region, at least one film layer in the light-emitting functional layer is disconnected at an edge of the defining structure, and second electrodes of adjacent sub-pixels are at least partially continuously arranged.

32-33. (canceled)

34. The manufacturing method according to claim 31, wherein before forming the inorganic nonmetallic material layer, the manufacturing method further comprises: forming a first insulating layer on the base substrate, wherein, in a partial region of the first region, the inorganic nonmetallic material layer is formed on a surface of the first insulating layer;
before forming the first insulating layer, the manufacturing method further comprises: forming a second insulating layer on the base substrate, wherein, in another partial region of the first region, the inorganic nonmetallic material layer is formed on a surface of the second insulating layer;
etching, by using the first gas, the inorganic nonmetallic material layer to form the defining pattern comprises simultaneously etching the inorganic nonmetallic material layer on the first insulating layer and the inorganic nonmetallic material layer on the second insulating layer to form the defining pattern;
etching, by using the second gas, the defining pattern to form the defining structure comprises simultaneously etching the defining pattern on the first insulating layer and the defining pattern on the second insulating layer to form the defining structure.
